(19) United States
(12) Patent Application Publication
(10) Pub. No.: US 2025/0124200 A1
(43) Pub. Date: Apr. 17, 2025

(54) MULTI-DIMENSIONAL PERFORMANCE MODELER

(71) Applicant: Wells Fargo Bank, N.A., San Francisco, CA (US)

(72) Inventors: Maria Chiarenza, Indian Trail, NC (US); Srinivas R. Doki, San Francisco, CA (US); Chris A. Feathers, San Francisco, CA (US); Rukiya Kelly, San Francisco, CA (US); Matt Shuck, San Francisco, CA (US); Richard Claude Robert Trent, Newton, NC (US); Jane Turpin, San Francisco, CA (US)

(73) Assignee: Wells Fargo Bank, N.A., San Francisco, CA (US)

(21) Appl. No.: 18/379,098

(22) Filed: Oct. 11, 2023

(51) Int. Cl. G06F 30/31

(52) U.S. Cl. CPC G06F 30/31

(57) ABSTRACT

Systems, methods and computer-readable storage media are utilized to model a multi-dimensional performance score. A processing circuit including memory and one or more processors is configured to authenticate a first exchanger and a second exchanger, receive a selection of at least one actionable element corresponding to an activity of the first exchanger and the second exchanger, identify a performance model based on the activity, collect at least one performance indicator associated with the first exchanger or the second exchanger, collect first activity data of the first exchanger and second activity data of the second exchanger, model the at least one performance indicator, the first activity data, and the second activity data to generate a MDP score, and provide the MDP score.

### TECHNICAL FIELD

The present disclosure relates generally to the field of performance analysis and content customization and presentation, including generation of a combined multi-dimensional performance score.

### BACKGROUND

In a computer networked environment such as the internet, entities such as people or companies provide content for display associated with a performance with the entity. Entities that provide the content typically provide content associated with the customer's performances and creditworthiness on an individual basis.

### SUMMARY

Some embodiments relate to a computer system. The system includes a processing circuit comprising memory and one or more processors. The processing circuit is configured to authenticate a first exchanger and a second exchanger, wherein at least one of the first exchanger or the second exchanger is associated with a provider. The processing circuit is also configured to receive a selection of at least one actionable element corresponding to an activity of the first exchanger and the second exchanger. The processing circuit is also configured to identify a performance model based on the selection of the activity. The processing circuit is also configured to collect at least one performance indicator associated with the first exchanger or the second exchanger. The processing circuit is also configured to collect first activity data of the first exchanger and second activity data of the second exchanger. The processing circuit is also configured to model, using the performance model, the at least one performance indicator, the first activity data, and the second activity data to generate a multi-dimensional performance (MDP) score. The processing circuit is also configured to provide, by the one or more processing circuits, the MDP score.

Some embodiments are related to a method. In some embodiments, the method includes authenticating, by one or more processing circuits, a first exchanger and a second exchanger, wherein at least one of the first exchanger or the second exchanger is associated with a provider. In some embodiments, the method also includes receiving, by the one or more processing circuits, a selection of at least one actionable element corresponding to an activity of the first exchanger and the second exchanger. In some embodiments, the method also includes identifying, by the one or more processing circuits, a performance model based on the selection of the activity. In some embodiments, the method also includes collecting, by the one or more processing circuits, at least one performance indicator associated with the first exchanger or the second exchanger. In some embodiments, the method also includes collecting, by the one or more processing circuits, first activity data of the first exchanger and second activity data of the second exchanger. In some embodiments, the method also includes modeling, by the one or more processing circuits using the performance model, the at least one performance indicator, the first activity data, and the second activity data to generate a multi-dimensional performance (MDP) score. In some embodiments, the method also includes providing, by the one or more processing circuits, the MDP score.

Some embodiments related to a computer-readable storage medium (CRM) having instructions stored thereon that, when executed by at least one processing circuit, causes the at least one processing circuit to perform operations. The operations include authenticating a first exchanger and a second exchanger, wherein at least one of the first exchanger or the second exchanger is associated with a provider. In some embodiments, the operations include receiving a selection of at least one actionable element corresponding to an activity of the first exchanger and the second exchanger. In some embodiments, the operations include identifying a performance model based on the selection of the activity. In some embodiments, the operations include collecting at least one performance indicator associated with the first exchanger or the second exchanger. In some embodiments, the operations include collecting first activity data of the first exchanger and second activity data of the second exchanger. In some embodiments, the operations include modeling, using the performance model, the at least one performance indicator, the first activity data, and the second activity data to generate a multi-dimensional performance (MDP) score. In some embodiments, the operations include providing the MDP score.

### BRIEF DESCRIPTION OF THE DRAWINGS

FIG. 1 is a block diagram depicting an example of a system for simulating a multi-dimensional performance score in a computing environment, according to some embodiments.

FIG. 2 is a block diagram illustrating an example computing system suitable for use in the various embodiments described herein.

FIG. 3 is a method of simulating a multi-dimensional performance score, according to some embodiments.

FIGS. 4A-4D are examples of computer-implemented graphical user interfaces, according to some embodiments.

### DETAILED DESCRIPTION

Referring generally to the figures, systems and methods are provided for modeling a multi-dimensional performance (MDP) score. In general, exchangers regularly engage in economic activities such as acquiring a loan (e.g., car loan or mortgage) from a provider, such as a service provide, bank, or financial institution. Providers typically assess the financial trustworthiness of exchangers to determine whether exchangers qualify for a loan. A plurality of exchangers may want to have their financial trustworthiness assessed collectively rather than individually because a collective assessment may improve an exchanger's chance of acquiring a loan. However, it may be difficult for a provider to assess the financial trustworthiness of certain exchangers. For example, some exchangers may not have a credit history. As a result, providers may not accurately assess the combined financial trustworthiness of a plurality of exchangers. Thus, a multi-dimensional performance (MDP) score can be generated and provided as an index or assessment indicating a combined trustworthiness, reliability, and/or dependability of two or more people. The MDP score can be used in a variety of joint activities, including car loans, mortgages, and other activities that involve co-exchangers. The MDP score can be used in a variety of joint activities, such as exchanges involving multiple exchangers. In particular, the modeler can generate an MDP score even if one of the simulation users is not affiliated with a relevant provider (e.g., institutional provider, a different provider). In some embodiments, the MDP score can be based on public and/or non-public data and information. Accordingly, the modeler can provide users the MDP score, a breakdown of the MDP score, and a list of recommended actions that the users can take to update their MDP score (e.g., increase, raise).

In terms of privacy, the disclosed system and methods also improves user information protection by employing a data privacy framework. Within this framework, the modeler can model multiple exchangers without directly sharing sensitive data related to each exchanger. Instead, performance indicators can be kept confidential and not disclosed between the joint exchanger. Through this approach, the modeler can update (e.g., calculate) the MDP score based on the inputs provided by one of the joint exchangers. That is, a first exchanger can securely provide authorization credentials to the provider, who will then verify the relationship between the first exchanger and the second exchanger. As a result, the provider can collect the second exchanger's performance indicators without requiring the first exchanger to share them explicitly. By implementing such a privacy-enhancing mechanism, the disclosed system and methods provide improvements to data privacy by ensuring that sensitive performance data remains protected and inaccessible to unauthorized parties. These improvements promote data privacy, granting each exchanger the assurance that their confidential information remains confidential throughout the modeling process.

For large, fixed-term instruments like economic allocations and other provisioning, providers typically rely on an exchanger's performance indicator (or indicators) to determine what type of economic allocation the exchanger will receive. Today, many exchangers share their personal finances with another person (e.g., a spouse or a co-habitant). For example, a married couple may have a shared economic account (e.g., bank account, card account, investment account). Consequently, many of these exchangers take out joint economic allocations for certain assets, including cars and real estate. Providers use different schemes to assess the trustworthiness, reliability, and/or dependability of joint exchangers. For example, an economic allocation provider can often rely on the “lower middle” FICO score. For example, if an exchanger's FICO scores from the three U.S. credit bureaus (e.g., Equifax, Experian, and TransUnion) are 723, 716, and 699, and a second exchanger's three FICO scores are 688, 657, and 649, the provider will use the 657 score, the lower of the two middle FICO scores, to calculate the exchangers' joint economic allocation.

The current methods of assessing the economic trustworthiness, reliability, and/or dependability of joint exchangers can be inaccurate or ineffectual. For example, the “lower middle” FICO relies on each exchanger's median FICO score, but one exchanger may have a median FICO score that is much larger than a second exchanger's FICO score. This, therefore, can lead to less favorable advances, which can harm joint exchangers' ability to build wealth over time. Additionally, an exchanger may not be able to produce or provide a FICO score. For example, an exchanger may not have a credit history (referred to herein as an “economic invisible exchanger”) and, as a result, no FICO score. Nevertheless, the economic invisible exchanger may engage in activities that provide insights about future borrowing practices. Accordingly, there is a need for an accurate joint assessment that can account for the economic trustworthiness, reliability, and/or dependability of users that are invisible to the provider. The present disclosure is directed to systems and methods for improving the assessment of joint exchangers.

In general, the disclosed systems and methods provide an accurate assessment of joint exchangers' economic trustworthiness (e.g., creditworthiness). In some embodiments, the MDP score is based on performance indicators and activity data. The MDP score can account for information that is otherwise not visible to the provider (e.g., activity data). All performance indicators and activity data may be accounted for in the final MDP score. Thus, the MDP score can provide a more accurate assessment of joint exchangers' economic trustworthiness.

The disclosed system and methods also account for economic invisible exchangers. In some embodiments, at least one exchanger is an economic invisible exchanger. An economic invisible exchanger can have no prior record (or identifiable record) of borrowing (i.e., no credit history or no identifiable credit history). Activity data, among other things, can account for information that helps assess the economic trustworthiness of an economic invisible exchanger. For example, activity data may include an exchanger's history of fraudulent activity. If one joint exchanger is engaged in fraudulent activity, this activity would contribute to a lower MDP score. However, repeated instances of fraudulent activity would lower the MDP score more than a few instances of fraudulent activity.

As used herein, “exchanger” refers to an individual seeking to have his or her economic trustworthiness (e.g., creditworthiness) evaluated. The exchanger may want to evaluate his or her economic trustworthiness for the purpose of an activity (e.g., acquiring debt, such as a car loan, mortgage, etc.). In some embodiments, the exchanger is a recognized exchanger. That is, the recognized exchanger satisfies requirements (e.g., proof of identity). In particular, the provider may designate the exchanger to be a recognized exchanger. The exchanger may include, but is not limited to, an exchanger affiliated with the provider, an economic invisible exchanger, and a foreign exchanger as described herein. It should be understood that the embodiments described herein may involve a plurality of exchangers. That is, some embodiments may describe a first exchanger and a second exchanger, but the embodiments described herein may involve more than just the first exchanger and the second exchanger.

As used herein, a “performance indicator” refers to any measurement of user/entity performance, often financially or economically related (e.g., person's borrowing practices). That is, performance indicators can illustrate whether a person is a reliable borrower (i.e., a person that makes payments on time, has a stable debt-to-income ratio, possesses a history of responsible credit use, and/or maintains a diverse mix of credit types). In some embodiments, performance indicators may involve qualitative data, quantitative data, or a combination of qualitative and quantitative data. Performance indicators may include, but are not limited to, a variety of well-established creditworthiness metrics, such as credit scores (e.g., FICO score and VantageScore), user debt-to-income (DTI) ratio, credit utilization ratio (CUR), payment history, length of credit history, credit mix, public credit records (e.g., bankruptcies, tax liens, judgements, foreclosures, etc.), and so on. In some embodiments, a performance indicator may be determined based on a plurality of performance indicators. For example, determining a credit score may involve analyzing a person's credit mix, payment history, and length of credit history. In some embodiments, the performance indicators are produced by one or more third-parties. For example, the credit score may be produced by credit bureaus (e.g., Equifax, Experian, or TransUnion). Performance indicators may affect a user's MDP score. For example, a low credit score may negative effect on a user's MDP score, but a low DTI ratio may have a positive effect on a user's MDP score. For example, a performance indicator could refer to credit score, credit report, debt-to-income ratio (DTI), payment history, income stability, debt utilization ratio, savings and asset levels, among other performance standards. In another example, a performance indicator could refer to net profit margin, return on investment (ROI), cash flow forecasts, equity ratios, liquidity ratios, or customer retention rates, each reflecting various aspects of an entity's financial health and operational efficiency. In particular, a performance indicator can be construed as a snapshot (e.g., real-time or near real-time) or representation of the financial health of an entity or account at a given point in time. It's a multidimensional concept that encapsulates various economic indicators such as the entity's solvency (its ability to meet long-term obligations), assets (what it owns), liabilities (what it owes), and other related financial markers. Often, the analysis system 110 can set rules for determining a performance indicator based on activity data. For example, one type of performance indicator, credit score is based on the activity data of amounts owed, new credit, length of credit history, payment history, credit mix, and so on.

As used herein, “activity data” refers to data of an account and/or identifier that is associated with economic or financial positions of the entity. That is, activity data may create inferences about a person's borrowing practices. In some embodiments, activity data may involve qualitative data, quantitative data, or a combination of qualitative and quantitative data. Activity data could refer to of bill payments, payment history, opening credit lines, amount owed, length of credit history, credit mix, new credit, closing credit lines, or debt repayment across at least one provider and includes at least one of performance indicator data, historical exchange settlements, and account exchange information. Furthermore, activity data may also encompass broader financial aspects such as revenue streams, expenditure patterns, asset management, liability assessments, investment portfolios, and overall fiscal strategies. Additionally, activity data may encompass real-time or near-real-time transactions, reflecting an up-to-the-minute snapshot of the entity's financial status. Activity data may include, but is not limited to, employment history, income stability, education level, professional qualifications, assets (liquid and non-liquid), criminal record, character and fitness, professional reputation, fiscal responsibility, and so on. In some embodiments, the activity data may be specific to a certain activity. For example, driving records (e.g., vehicle accident reports) may be relevant activity data for a car loan and home activities (e.g., property damage) may be relevant activity data for a mortgage. Activity data may also affect a user's MDP score. For example, a user that has a history of fraudulent activity is probably less likely to pay back. A user with a history of fraudulent activity, therefore, would likely have a lower MDP score than a user without such a history. In some embodiments, performance indicators correspond to a user's credit history and include at least one of a user's performance indicator data, historical exchange settlements, account exchange information across at least one provider, and other similar data. “Future activity data” refers to the above defined activity data that a user may take in the future.

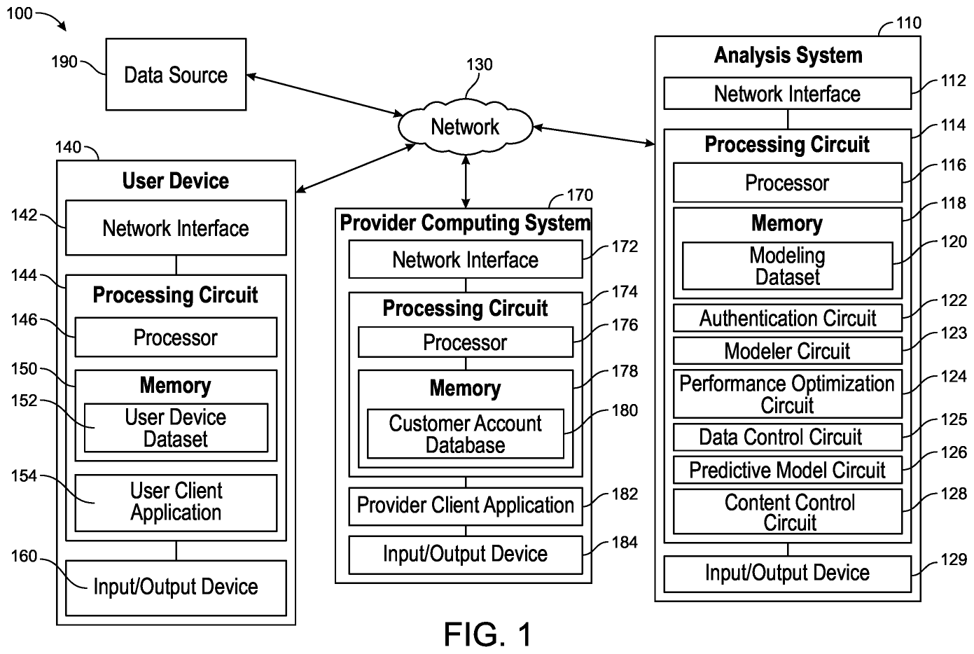

Referring to FIG. 1, a block diagram of modeler system 100 is shown, according to potential embodiments. Modeler system 100 (e.g., sometimes referred to herein as the “multi-dimensional performance score system”) includes provider computing system 170 associated with a provider, such as a service provider, bank, or financial institution. Modeler system 100 further includes one or more user devices (e.g., user device 140), analysis system 110, and one or more data sources (e.g., data source 190). In some embodiments, provider computing system 170, user device 140, analysis system 110, and data source 190 are directly (or indirectly) communicably coupled. In some embodiments, the components of modeler system 100 may be communicably and operatively coupled to each other over a network, such as network 130, that permits the direct or indirect exchange of data, values, instructions, messages, and the like (represented by the double-headed arrows in FIG. 1). Network 130 may include one or more of a cellular network, the Internet, Wi-Fi, Wi-Max, a proprietary provider network, a proprietary retail or service provider network, and/or any other kind of wireless or wired network.

Each system or device in modeler system 100 may include one or more processors, memories, network interfaces (sometimes referred to herein as a “network circuit”) and user interfaces. The memory may store programming logic that, when executed by the processor, controls the operation of the corresponding computing system or device. The memory may also store data in databases. For example, memory 178 may store programming logic that, when executed by processor 176 within processing circuit 174, causes customer account database 180 to update information for a customer account with communications received from user device 140. The memory may also store data in a dataset. For example, memory 118 may store programming logic that, when executed by processor 116 within processing circuit 114, causes modeling dataset 120 to update with information received from data source 190. Network interfaces (e.g., network interface 172 of provider computing system 170, sometimes referred to herein as a “network circuit”) may allow computing systems and devices to communicate wirelessly or otherwise. The various components of devices in modeler system 100 may be implemented via hardware (e.g., circuitry), software (e.g., executable code), or any combination thereof. Devices and components in FIG. 1 can be added, deleted, integrated, separated, and/or rearranged in various embodiments of the disclosure.

Provider computing system 170 may be managed by a provider, such as a credit card issuer, a consultant, a retailer, a service provider, and/or the like. Provider computing system 170 includes network interface 172, processing circuit 174, and input/output device 184. Network interface 172 is structured and used to establish connections with other computing systems and devices (e.g., user devices 140, analysis system 110, data source 190, etc.) via network 130. Network interface 172 includes program logic that facilitates connection of provider computing system 170 to network 130. For example, network interface 172 may include any combination of a wireless network transceiver (e.g., a cellular modem, a Bluetooth transceiver, a WiFi transceiver, etc.) and/or a wired network transceiver (e.g., an Ethernet transceiver). In some embodiments, network interface 172 includes the hardware (e.g., processor, memory, and so on) and machine-readable media sufficient to support communication over multiple channels of data communication. Further, in some embodiments, network interface 172 includes cryptography capabilities to establish a secure or relatively secure communication session in which data communicated over the session is encrypted. In various embodiments, analysis system 110 can adapt to network traffic needs by compressing content, by any computing device described herein, and sending it (e.g., via network 130) to various other computing devices, by adjusting security filters to remove junk traffic off network 130 (e.g., by monitoring packets), and so on.

Processing circuit 174 includes processor 176, memory 178, and provider client application 182. Memory 178 may be one or more devices (e.g., RAM, ROM, Flash memory, hard disk storage) for storing data and/or computer code for completing and/or facilitating the various processes described herein. Memory 178 may be or include non-transient volatile memory, non-volatile memory, and non-transitory computer storage media. Memory 178 may include database components, object code components, script components, or any other type of information structure for supporting the various activities and information structures described herein. Memory 178 may be communicably coupled to processor 176 and include computer code or instructions for executing one or more processes described herein. Processor 176 may be implemented as one or more application specific integrated circuits (ASICs), field programmable gate arrays (FPGAs), a group of processing components, or other suitable electronic processing components. As such, provider computing system 170 is configured to run a variety of application programs and store associated data in a database of memory 178 (e.g., customer account database 180). One such application may be provider client application 182.

Memory 178 may store customer account database 180, according to some embodiments. Customer account database 180 may be configured to store updated personal information for customer accounts associated with the provider (e.g., the FI). For example, customer account database 180 saves personal user information, such as name, age, gender, address, education, occupation, etc., customer preferences, such as notification preferences, security preferences, etc., and authentication information, such as customer passwords, biometric data for the customer, geometric information (e.g., latitude, longitude), etc. Customer account database 180 can also save information about a user's relationship to other people (e.g., spouse, co-habitant, friend, etc.), which may or may not be affiliated with the provider. In some embodiments, customer account database 180 includes a token vault that stores an associated customer token and/or device token for each customer account. Customer account database 180 may further be configured to store financial data for each customer account, such as past transactions, different provider account information (e.g., balances, debt, type of account, etc.), investments, loans, mortgages, and so on.

In some embodiments, provider client application 182 may be incorporated with an existing application in use by provider computing system 170 (e.g., a mobile provider application, a service provider application, etc.). In other embodiments, provider client application 182 is a separate software application implemented on provider computing system 170. Provider client application 182 may be downloaded by provider computing system 170 prior to its usage, hard coded into memory 178 of provider computing system 170 or be a network-based or web-based interface application such that provider computing system 170 may provide a web browser to access the application, which may be executed remotely from provider computing system 170. Accordingly, provider computing system 170 may include software and/or hardware capable of implementing a network-based or web-based application. For example, in some instances, provider client application 182 includes software such as HTML, XML, WML, SGML, PHP (Hypertext Preprocessor), CGI, and like languages.

In the latter instance, a user (e.g., a provider employee) may log onto or access the web-based interface before usage of the provider client application 182. In this regard, provider client application 182 may be supported by a separate computing system (e.g., user device 140) including one or more servers, processors (e.g., processor 146), network interface 142 (sometimes referred to herein as a “network circuit”), and so on, that transmit applications for use to provider computing system 170. In certain embodiments, provider client application 182 includes an application programming interface (API) and/or a software development kit (SDK) that facilitate the integration of other applications with provider client application 182. For example, provider client application 182 is configured to utilize the functionality of user device 140 by interacting with user client application 154 through an API.

Still referring to FIG. 1, input/output device 184 is structured to receive communications from and provide communications to provider employees associated with provider computing system 170. Input/output device 184 is structured to exchange data, communications, instructions, etc. with an input/output component of provider computing system 170. In one embodiment, input/output device 184 includes communication circuitry for facilitating the exchange of data, values, messages, and the like between input/output device 184 and the components of provider computing system 170. In yet another embodiment, input/output device 184 includes machine-readable media for facilitating the exchange of information between input/output device and the components of provider computing system 170. In yet another embodiment, input/output device 184 includes any combination of hardware components, communication circuitry, and machine-readable media.

In some embodiments, input/output device 184 includes suitable input/output ports and/or uses an interconnect bus (not shown) for interconnection with a local display (e.g., a touchscreen display) and/or keyboard/mouse devices (when applicable), or the like, serving as a local user interface for programming and/or data entry, retrieval, or other user interaction purposes. As such, input/output device 184 may provide an interface for the user to interact with various applications (e.g., provider client application 182) stored on provider computing system 170. For example, input/output device 184 includes a keyboard, a keypad, a mouse, joystick, a touch screen, a microphone, a biometric device, a virtual reality headset, smart glasses, smart headsets, and the like. As another example, input/output device 184, may include, but is not limited to, a television monitor, a computer monitor, a printer, a facsimile, a speaker, and so on. As used herein, virtual reality, augmented reality, and mixed reality may each be used interchangeably yet refer to any kind of extended reality, including virtual reality, augmented reality, and mixed reality.

Analysis system 110 includes network interface 112, processing circuit 114, and an input/output device 129. Network interface 112, processing circuit 114, and input/output device 129 may function substantially similar to and include the same or similar components as the components of provider computing system 170, such as network interface 172, processing circuit 174, and input/output device 184, described above. As such, it should be understood that the description of network interface 172, processing circuit 174, and input/output device 184 of provider computing system 170 provided above may be similarly applied to network interface 112, processing circuit 114, and input/output device 129 of analysis system 110.

For example, network interface 112 is similarly structured and used to establish connections with other computing systems (e.g., provider computing system 170, user devices 140, and/or data source 190) via network 130. Network interface 112 may further include any or all of the components discussed above, with reference to network interface 172.

Processing circuit 114 similarly includes processor 116 and memory 118. Processor 116 and memory 118 are substantially similar to the processor 176 and memory 178 described above, with reference to provider computing system 170. In some embodiments, memory 118 includes modeling dataset 120. Modeling dataset 120 may be structured to store data from data source 190 concerning exchangers (e.g., customers associated with the provider). In some embodiments, the data includes an exchanger's performance indicators and activity data. Performance indicators and activity data may help the provider assess the creditworthiness of exchangers.

Processing circuit 114 also is also shown to include an authentication circuit 122. Authentication circuit 122 may be configured to determine whether a user is authenticated to initiate a provider session and/or to complete certain provider tasks. For example, authentication circuit 122 may be configured to request an authorization approval from provider computing system 170 of a received PIN or biometric input. In some embodiments, authentication circuit 122 is also configured to determine the level of authentication necessary to complete different types of financial tasks (e.g., take out a loan, change address, request new credit card, etc.). Authentication circuit 122 may be configured to generate a score of how authenticated a user is during a provider session. For example, a user that entered both a biometric input and an alphanumeric passcode may receive a first score of 100% authenticated, and a user that only entered a PIN may receive a second score of 50% authenticated.

In some embodiments, authentication circuit 122 allows a first exchanger to calculate the MDP score for the first exchanger and a second exchanger. After the relationship status between the first exchanger and the second exchanger is verified according to at least one of the processes described above, authentication circuit 122 can grant the first exchanger access to the performance indicators and activity data of the second exchanger included in modeling dataset 120 stored on memory 118. Furthermore, authentication circuit 122 may issue a notification to the second exchanger via user device 140, wherein the notification indicates that the first exchanger is accessing the performance indicators and activity data of the second exchanger to generate a MDP score. In some embodiments, the performance indicators and activity data of the second exchanger may be invisible to the first exchanger to protect the privacy of the second exchanger but are nonetheless figured into the MDP score. The second exchanger may not want to share performance indicators or activity data with the first exchanger if the relationship status between the first exchanger and the second exchanger changes (e.g., divorce).

Processing circuit 114 is also shown to include modeler circuit 123. In some embodiments, modeler circuit 123 is configured to receive data from modeling dataset 120. Modeler circuit 123 uses a performance model to model the performance indicators and the activity data of the exchangers. In some embodiments, modeler circuit 123 generates a MDP score based on the performance indicators and activity data of the exchangers. Modeler circuit 123 may retrieve the performance indicators and activity data stored in modeling dataset 120 in response to a modeling activity. In some embodiments, the modeling activity involves retrieving performance indicators and activity data to calculate a MDP score. Modeler circuit 123 determines which performance indicators and activity data are the most important for the MDP score calculation. In some embodiments, the performance score can assign a performance score weight (PSW) to each performance indicator and each activity data, and each PSW depends on a plurality of risk assessment factors.

In some embodiments, risk assessment factors may include, but are not limited to, predictive power (e.g., the relationship between a performance indicator or activity data and a certain activity outcome), history (e.g., changes to a performance indicator or activity data over time), financial impact (e.g., impact on financial stability), activity-specific considerations (e.g., prior homeownership may be relevant for a mortgage while prior car ownership may be relevant for a car loan), and so on. For example, a performance indicator (e.g., credit score) may have a higher PSW than an activity data (e.g., education level) because credit scores may be a more accurate metric of creditworthiness than an exchanger's education level. That is, a lower credit score is more likely to consistently result in a negative activity outcome (e.g., loan refusal) compared to a low education level (e.g., a person with no post-secondary education). Additionally, risk assessment factors might encompass behavioral attributes, such as an exchanger's spending patterns, repayment history, or frequency of credit inquiries, since these can indicate a propensity towards financial risk-taking or caution. Other factors could involve external economic indicators, like prevailing interest rates, unemployment rates in an exchanger's region, or broader economic downturns, which could potentially influence an exchanger's financial stability and ability to repay.

The processing circuit 114, interacting (e.g., communicating with by sending requests and/or commands/signals) with the memory 118 can store a variety of data in the modeling dataset 120, according to some embodiments, including performance scores and multi-dimensional performance (MDP) scores. The modeling circuit 123 can use data stored in the modeling dataset 120 and other gathered data to generate MDP scores which could then be stored in the modeling dataset 120. The modeling dataset 120 may also be configured to store a user data structure which can include updated personal information for customer accounts associated with the provider (e.g., the FI). For example, the modeling dataset 120 can store personal user information that models account activity affecting performance indicators, such as previous exchanges for loans, bills, credit card payments, payments to other accounts either owned or not owned by the user, among other exchanges. The modeling dataset 120 can store other personal user information used in modeling activity such as name, age, gender, address, education, occupation, etc., customer preferences, such as notification preferences, security preferences, etc., and authentication information, such as customer passwords, biometric data for the customer, geometric information (e.g., latitude, longitude), etc. The modeling dataset 120 may further be configured to store financial data for each customer account, such as past transactions, different provider account information (e.g., balances, debt, type of account, etc.), investments, loans, mortgages, and so on.

In some embodiments, the memory 118 and modeling dataset 120 may be communicably coupled to the modeler circuit 123. The modeler circuit 124 can implement modeling operations of the analysis system 110. In various arrangements, the modeler circuit 124 can be configured to receive a plurality of data from a plurality of data sources (e.g., memory 118, modeling dataset 120, authentication circuit 122, performance optimization circuit 124, data control circuit 125, predictive model circuit 126, content control circuit 128, user device 140, provider computing systems 170, and data source 170) via one or more data channels (e.g., over network 130). Each data channel may include a network connection (e.g., wired, wireless, cloud) between the devices or systems and the analysis system 110. For example, the modeler circuit 123 could query the memory 118 for data of the modeling dataset 120 and use the modeling data to generate a MDP score that models one or more exchangers performance indicators and activity data of the exchangers.

The modeler circuit 123 can be further configured to receive new activity data or an updated performance indicator from the input/output device 129 of the analysis system 110 or from the modeling dataset 120. For example, the modeler circuit 123 may be configured to continuously monitor and receive new information from a user device 140, data source 170, or provider computing system 170 via the network 130 and determine the effect on the one or more MDP scores. New data can affect the modeling dataset 120 and thereon after the modeler circuit 123 and other parts of the analysis system 110. For example, a user could pay off a previous debt after their activity data has already been sent to the analysis system 110. A source (e.g., user device 140) may then send the activity data, (e.g., debt payment) to the analysis system 110. Because debt payment can be a significant factor affecting the performance indicator of a particular exchangers (and possibly affect the MDP score), not only would the modeling dataset 120 be updated, but the modeler circuit 123 could update the MDP score. For example, the debt payment could cause the modeler circuit 123 to change the credit capabilities of the collective exchangers, which affects what products and actionable activities are available to the collective exchangers.

In some embodiments, modeler circuit 123 uses modeling dataset 120 and a plurality of performance models to generate a plurality of MDP scores. The information in modeling dataset 120 (i.e., the performance indicators and activity data) may be used by multiple performance models. For example, multiple performance models may rely on an exchanger's credit score. Other information in modeling dataset 120 may only be relevant to certain performance models. For example, an exchanger's history of traffic accidents may be relevant to a performance model based on a car loan but not relevant to a performance model based on a mortgage.

Referring specifically to the plurality of performance models, each performance model can carry its own distinct set of criteria and parameters, optimized for particular scenarios or economic activities. For example, a performance model focused on evaluating exchangers for potential homeownership may prioritize factors such as stable income, previous property management experience, and history of consistent mortgage or rent payments. Another model aimed at predicting the reliability of borrowers for personal loans might emphasize credit utilization, diversity of credit lines, and frequency of recent credit inquiries. In some embodiments, the process of selecting the performance model from the pool of available models can be based on the type of financial or economic activity being considered, the specific data available for the exchanger, and the objective of the score evaluation. If the activity relates to automobile financing, a model that places significant weight on both exchanger's past vehicle ownership, driving histories, and related insurance claims might be selected.

Given the MDP score's capability to represent the collective creditworthiness of multiple exchangers, the chosen performance model is employed to accommodate varied data points and identify patterns that indicate collective reliability or potential risks. This may include one or more computational algorithms (or other software algorithms) that analyze the correlations between the credit behaviors of individual exchangers within the group, detecting synergies or discrepancies that could impact the overall score. As more data gets fed into the system, especially from varied group compositions and their subsequent economic activities, the performance models can be refined. Over time, this iterative process provides that the system's predictions and MDP score assignments remain accurate and relevant. In some embodiments, when a credit invisible individual is part of modeling, the modeler circuit 123 might opt for a performance model tailored to handle a mixture of quantifiable credit data and qualitative or alternative data sources. For example, the model could place weight on the available credit score of the one individual but would also consider non-traditional factors for the credit invisible person. This might include rent payment history, utility bill payments, employment history, personal references, among others.

Processing circuit 114 is also shown to include performance optimization circuit 124. In some embodiments, performance optimization circuit 124 is configured to receive or collect the MDP score generated by modeler circuit 123. The performance optimization circuit 124 can generate a list of actionable recommendations to improve the MDP score. Some of the actionable recommendations may be generally applicable regardless of the performance model used to generate the MDP score. For example, performance optimization circuit 124 can provide suggestions for how the exchanger can supplement their savings (e.g., refinancing existing loans). In another example, performance optimization circuit 124 can provide suggestions for how the exchanger can reduce repayments (e.g., closing open credit accounts). Other actionable recommendations are based on the performance model used to generate the MDP score. For example, performance optimization circuit 124 may generate a list of sources to improve driving if the activity data is related to poor driving. In some embodiments the degree of actionable recommendations may vary based on the MDP score. For example, a user may generate a larger list of recommendations for a lower score MDP score compared to a higher MDP score.

Processing circuit 114 is also shown to include data control circuit 125. In some embodiments, data control circuit 125 is configured to manage data transmitted across network 130. Data control circuit 125 can take certain measures to mitigate traffic across network 130. For example, data control circuit 125 may reprioritize network traffic, compress data, or reallocate network bandwidth, among other things. In some embodiments, data control circuit 125 conducts a diagnostic test to evaluate the status of network 130. Data control circuit 125 resolves potential issues with network 130 based on the results of the diagnostics test. In some embodiments, data control circuit 125 manages data transmitted across network 130 between data source 190 and modeling dataset 120.

Processing circuit 114 is also shown to include predictive model circuit 126. In some embodiments, predictive model circuit 126 uses artificial intelligence (AI) or other machine learning techniques to anticipate what performance models will be the most relevant to the exchanger. For example, predictive model circuit 126 may use online search history to determine which performance model is most relevant to the exchanger (e.g., search results for a car means a car loan may be relevant). In some embodiments, predictive model circuit 126 ranks the performance models based on relevancy. In some embodiments, the artificial intelligence used by predictive model circuit 126 are machine learning algorithms. The machine learning algorithms used by predictive model circuit 126 can include, among others, nearest neighbor, naive bayes, decision tree, linear regression, support vector machine, and neural networks. The machine learning algorithms can be implemented using any standard computer-compatible programming language including Java, Python, and C.

Accordingly, the modeler circuit 123 functions as a repository and evaluator of various performance models, taking into account the diverse data aspects from modeling dataset 120. Additionally, the predictive model circuit 126 anticipates the user's needs even before they explicitly surface, harnessing the power of AI and machine learning to foresee the most suitable performance model. When an event or change is detected that may influence an exchanger's financial behavior, like an online search hinting at a potential car purchase, predictive model circuit 126 might preemptively rank the car loan performance model higher. In scenarios where both circuits have potential models to suggest, a hierarchical or collaborative decision-making mechanism could be invoked. This might work in a variety of ways. In a hierarchical approach, one circuit, perhaps the predictive model circuit 126 due to its foresight capabilities, might have the final determinization in model selection after considering the modeler circuit 123's recommendation. Conversely, in a collaborative mechanism, both circuits could engage in a “voting” or “weighting” system where each proposes a model along with a confidence score. The model with the highest combined confidence, factoring in both the relevance determined by the modeler circuit 123 and the foresight of predictive model circuit 126, would be selected. Thus, the collaboration provides that the chosen model is not just based on historical and current data but also aligned with anticipated future actions and needs of the exchanger.

Processing circuit 114 is also shown to include content control circuit 128. In some embodiments, content control circuit 128 receives data from modeler circuit 123, including the MDP score, and data from performance optimization circuit 124, including actionable recommendations. Content control circuit 128 controls the information that is displayed on a user device 140. For example, content control circuit 128 can transmit a MDP score and actionable recommendations to user device 140 via network 130. In some embodiments, content control circuit 128 can transmit an error message to user device 140 if modeler circuit 123 is unable to generate a MDP score. For example, the error message may notify the user that modeling dataset 120 includes an insufficient amount of activity data to generate a reliable MDP score.

The content control circuit 128 can include circuitry for storing information such as rules for offering actionable activities for an MDP score. The content control circuit 128 can receive data for determining or displaying actionable activities to the user from any component of the modeling system 100. The content control circuit 128 may additionally store this information in memory 118. In some embodiments, the content control circuit 128 can generate content for displaying to users. The content can be selected from various resources (e.g., an update for an MDP score sent from the data control circuit 125). The content control circuit 128 can also be structured to provide content (e.g., via a graphical user interface (GUI)) to the user device 140 over the network 130, for display within the resources. For example, the content control circuit 128 can present a GUI including actionable elements (or just an MDP score) and a message associated with the actionable activity that may affect the MDP score. The GUI can be sent via the I/O device 129 to the user device 140 through the network 130.

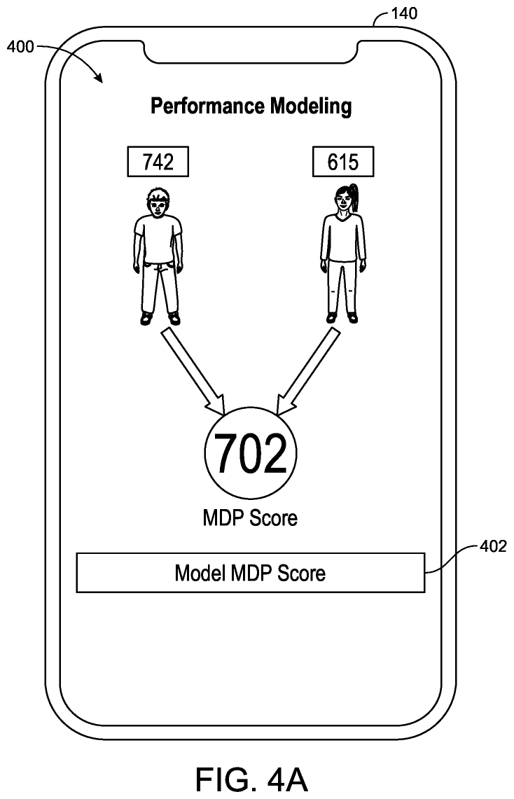

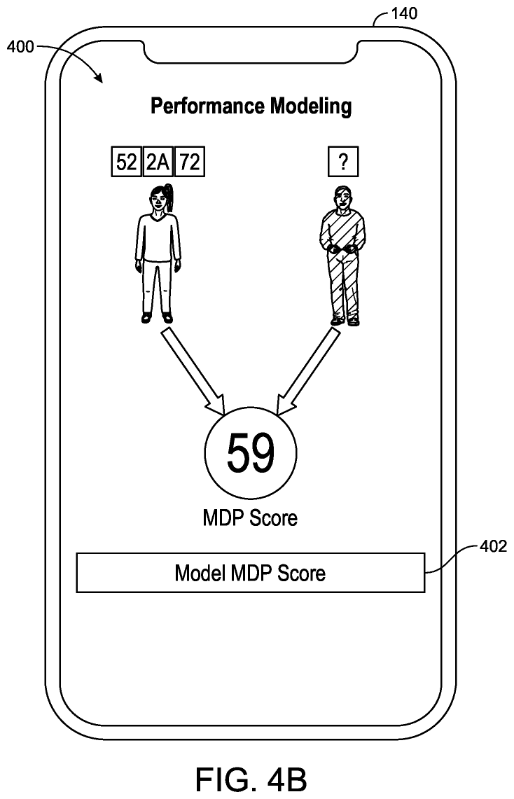

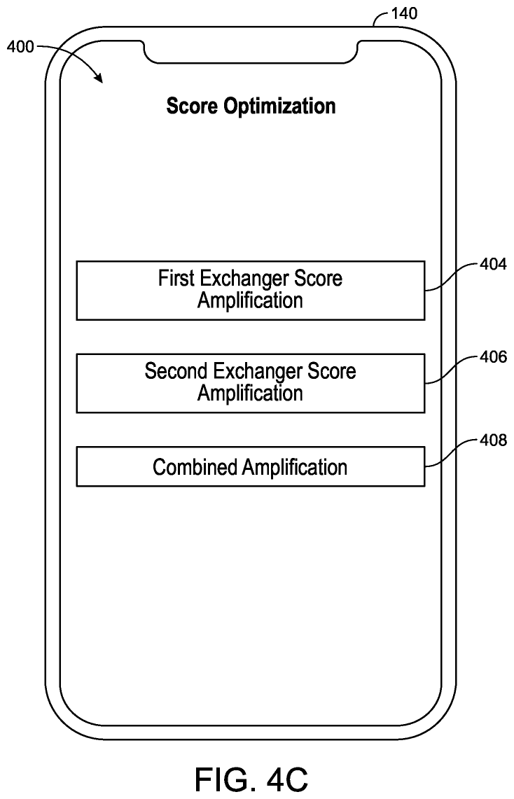

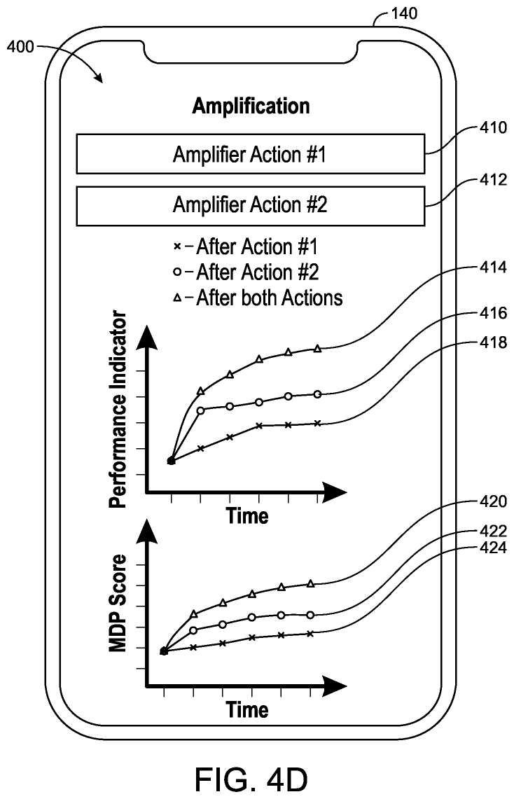

The content control circuit 128 can generate interfaces such as a plurality of customized dashboards, such as those described in detail below, with reference to FIGS. 4A-4D. The content control circuit 128 can generate customized user-interactive dashboards for one or more entities, such as the user device 140, based on data received from the user device 140, data source 190, and/or any other computing device described therein. The generated dashboards can include various data (e.g., data stored in the content control circuit 128 and/or modeling dataset 120) associated with one or more entities such as a user data structure, performance indicators, past, current, or future exchange history, account information, multidimensional scores, actionable activities/executables, and/or others. In certain embodiments, the analysis system 110 includes an application programming interface (API) and/or a software development kit (SDK) that facilitate the integration of other applications with the analysis system 110. For example, the analysis system 110 is configured to utilize the functionality of the user device 140 interacting with the user client application 154 through an API.

In some embodiments, processing circuit 114 may be configured to authenticate a first exchanger and a second exchanger (sometimes referred to herein as “exchangers”), wherein at least one of the first exchanger or the second exchanger is associated with a provider. In particular, processing circuit 114 may be configured to verify the login credentials of the exchanger associated with the provider. In some embodiments, processing circuit 114 may be further configured to receive a selection of at least one actionable element corresponding to an activity of the first exchanger and the second exchanger. In particular, the actionable element may be a borrowing request (e.g., mortgage, car loan, student loan, etc.). In some embodiments, processing circuit 114 may be further configured to identify a performance model based on the selection of the activity. For example, processing circuit 114 may choose a first performance model for a mortgage and a second performance model for a car loan. In some embodiments, processing circuit 114 may be further configured to collect at least one performance indicator associated with the first exchanger or the second exchanger and collect first activity data of the first exchanger and second activity data of the second exchanger. The performance indicators and activity data may include the information described above. In some embodiments, processing circuit 114 may be further configured to model, using the performance model, the at least one performance indicator, the first activity data, and the second activity data to generate a multi-dimensional performance (MDP) score. In particular, processing circuit 114 may define performance metrics, normalize the performance metrics, assign weights to the performance metrics, and calculate weighted scores for each performance metric. The performance metrics may include performance indicators and activity data. In some embodiments, processing circuit 114 may be further configured to provide the MDP score. In particular, processing circuit 114 may provide the MDP score via user client application 154 on user device 140.

Still referring to FIG. 1, data source 190 is configured to provide data to a user device 140, provider computing system 170, and analysis system 110 via network 130. The data may be part of a user device dataset 152, customer account database 180, or modeling dataset 120. In some embodiments, data source 190 is a third-party data broker. For example, the provider may request an exchanger's credit information (e.g., a credit score) from a credit bureau (e.g., Equifax, Experian, and TransUnion). In some embodiments, data source 190 is public information. For example, a public record, accessible via the internet, may contain activity data (e.g., information about a driver's accident history).

The computing system 200 includes a bus 205 or other communication component for communicating information and a processor 210 coupled to the bus 205 for processing information. The computing system 200 also includes main memory 215, such as a random-access memory (RAM) or other dynamic storage device, coupled to the bus 205 for storing information, and instructions to be executed by the processor 210. Main memory 215 can also be used for storing position information, temporary variables, or other intermediate information during execution of instructions by the processor 210. The computing system 200 may further include a read only memory (ROM) 220 or other static storage device coupled to the bus 205 for storing static information and instructions for the processor 210. A storage device 225, such as a solid-state device, magnetic disk or optical disk, is coupled to the bus 205 for persistently storing information and instructions.

The computing system 200 may be coupled via the bus 205 to a display 235, such as a liquid crystal display, or active-matrix display, for displaying information to a user. An input device 230, such as a keyboard including alphanumeric and other keys, may be coupled to the bus 205 for communicating information, and command selections to the processor 210. In another arrangement, the input device 230 has a touch screen display 235. The input device 230 can include any type of biometric sensor, a cursor control, such as a mouse, a trackball, or cursor direction keys, for communicating direction information and command selections to the processor 210 and for controlling cursor movement on the display 235.

In some arrangements, the computing system 200 may include a communications adapter 240, such as a networking adapter. Communications adapter 240 may be coupled to bus 205 and may be configured to enable communications with a computing or communications network 130 and/or other computing systems. In various illustrative arrangements, any type of networking configuration may be achieved using communications adapter 240, such as wired (e.g., via Ethernet), wireless (e.g., via Wi-Fi, Bluetooth), satellite (e.g., via GPS) pre-configured, ad-hoc, LAN, WAN.

According to various arrangements, the processes that effectuate illustrative arrangements that are described herein can be achieved by the computing system 200 in response to the processor 210 executing an arrangement of instructions contained in main memory 215. Such instructions can be read into main memory 215 from another computer-readable medium, such as the storage device 225. Execution of the arrangement of instructions contained in main memory 215 causes the computing system 200 to perform the illustrative processes described herein. One or more processors in a multi-processing arrangement may also be employed to execute the instructions contained in main memory 215. In alternative arrangements, hard-wired circuitry may be used in place of or in combination with software instructions to implement illustrative arrangements. Thus, arrangements are not limited to any specific combination of hardware circuitry and software.

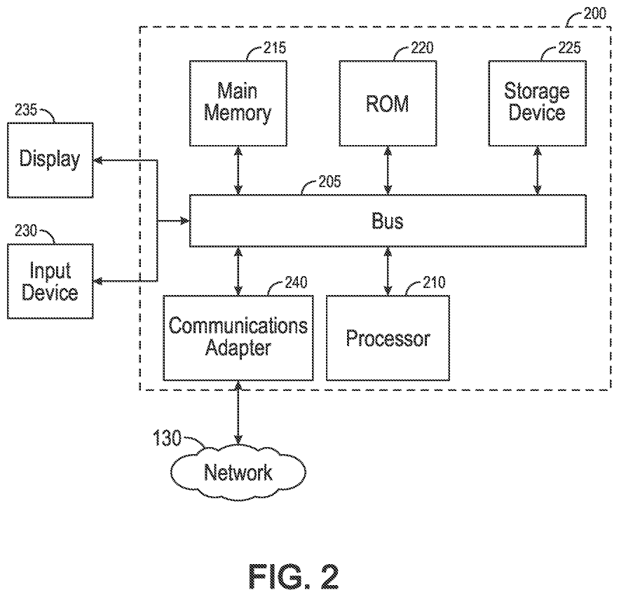

That is, although an example processing system has been described in FIG. 2, arrangements of the subject matter and the functional operations described in this specification can be carried out using other types of digital electronic circuitry, or in computer software (e.g., application, blockchain, distributed ledger technology) embodied on a tangible medium, firmware, or hardware, including the structures disclosed in this specification and their structural equivalents, or in combinations of one or more of them. Arrangements of the subject matter described in this specification can be implemented as one or more computer programs, e.g., one or more subsystems of computer program instructions, encoded on one or more computer storage medium for execution by, or to control the operation of, data processing apparatus. Alternatively, or in addition, the program instructions can be encoded on an artificially generated propagated signal, e.g., a machine generated electrical, optical, or electromagnetic signal, which is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices). Accordingly, the computer storage medium is both tangible and non-transitory.

Although shown in the arrangements of FIG. 2 as singular, stand-alone devices, one of ordinary skill in the art will appreciate that, in some arrangements, the computing system 200 may include virtualized systems and/or system resources. For example, in some arrangements, the computing system 200 may be a virtual switch, virtual router, virtual host, virtual server. In various arrangements, computing system 200 may share physical storage, hardware, and other resources with other virtual machines. In some arrangements, virtual resources of the network 130 (e.g., network 130 of FIG. 1) may include cloud computing resources such that a virtual resource may rely on distributed processing across more than one physical processor, distributed memory, etc.

As used herein, the term “resource” refers to a physical or virtualized (for example, in cloud computing environments) computing resource needed to execute computer-based operations. Examples of computing resources include computing equipment or device (server, router, switch, etc.), storage, memory, executable (application, service, and the like), data file or data set (whether permanently stored or cached), and/or a combination thereof (for example, a set of computer-executable instructions stored in memory and executed by a processor, computer-readable media having data stored thereon, etc.).

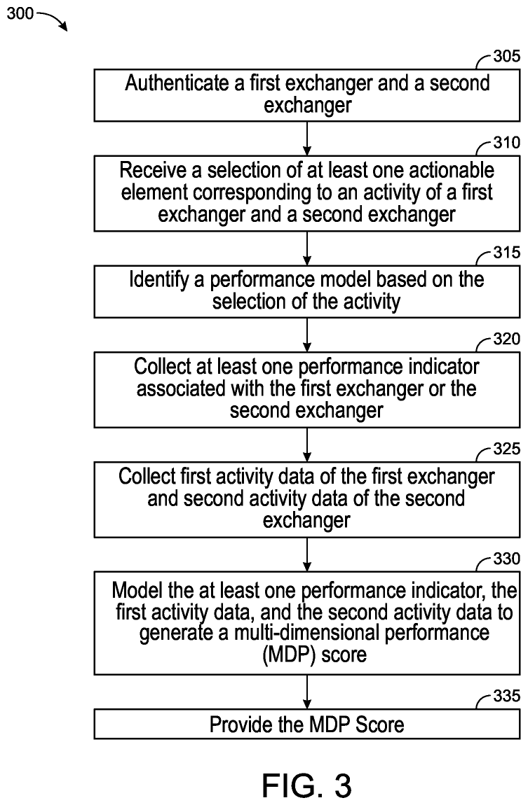

Referring now to FIG. 3, a flow diagram of method 300 for simulating a MDP score with modeler system 100 of FIG. 1, according to example embodiments. The method may be provided by and/or accessible by provider computing system 170, user devices 140, and analysis system 110, for example. Method 300 may be performed by analysis system 110 described above pertaining to FIGS. 1 and 2. Additional, fewer, or different operations may be performed depending on the particular arrangement. In some embodiments, some, or all operations of method 300 may be performed by one or more processors executing on one or more computing devices, systems, or servers. In various embodiments, each operation may be re-ordered, added, removed, or repeated.

In some embodiments, method 300 begins in response to receiving, by analysis system 110, a session trigger event. A session trigger event may be any event that triggers the beginning of a session between analysis system 110 and user device 140. For example, a session trigger event may include a customer or employee logging into user client application 154 on user device 140 and selecting a MDP calculator software application. User client application 154 may be accessible via any user device that functions as a computing system, including a smartphone, a tablet, a desktop computer, a laptop, etc.

At step 305, one or more processing circuits authenticate a first exchanger and a second exchanger. In some embodiments, the first exchanger and the second exchanger may be affiliated or associated with the provider. In some embodiments, only one or none of the exchangers may be affiliated with or associated with the provider. In particular, an exchanger affiliated with the provider may have a customer account with the provider or may have previously interacted with the provider (e.g., made a transaction, left a review, communicated with). Exchangers affiliated with the provider may submit one or more access indicia to the provider via user device 140 as part of the authentication process. Access indica may include, but are not limited to, a username, a password (e.g., alphanumeric password or a PIN code), biometric information, or a combination of several access indicia. In some embodiments, authenticating the user may involve submitting access indicia and completing a secondary authentication process. A secondary authentication process may involve responding to one or more user action requests for a multi-factor authentication system (e.g., responding to a notification on a user device, submitting a PIN, answering a call on a user device, etc.). In response to a successful user authentication, the user may be granted access to user client application 154.

In some embodiments, the processing circuits establishes a user session on user device 140 in response to authenticating the user. During the user session, user device 140 may assign session tokens or cookies to maintain the authenticated state during subsequent interactions. In some embodiments, the processing circuits performs additional authorization checks to determine the user's level of access or permissions within the system. The processing circuits may revoke a user's access to user client application 154 if the user no longer has permission to access user client application 154. Revoking user access to user client application 154 may involve the processing circuits transmitting a revocation signal to user device 140.

In some embodiments, authentication circuit 122 is configured to determine whether authentication for the provider session is successful. In some embodiments, authentication circuit 122 is configured to determine whether authentication for the provider session is successful. In some embodiments, authentication circuit 122 is configured to receive access indicia (e.g., a personal identifier number (PIN), username/password combination, reading of biometric information, etc.). A fraud detection system (not shown) within authentication circuit 122 ensures each joint exchanger associated with a provider has a unique access indicia. Network interface 142 may transmit, via network 130, the received input to the processing circuits. In some embodiments, the processing circuits then determines whether the received input matches user information stored in a database (e.g., in customer account database 180). For example, the processing circuits determines whether a device token received from user device 140 matches a token stored in a token vault of customer account database 180. Network interface 142 may then receive confirmation or a denial of authentication for the one or more users (e.g., a customer, more than one customer, etc.). In some embodiments, authentication circuit 122 is configured to execute step 305 at certain intervals throughout a provider session. For example, after a predetermined time interval, or at the end of a scheduled provider session, authentication circuit 122 may be configured to re-authenticate the one or more customers.

In some embodiments, at least one of the first exchanger or the second exchanger may not be affiliated with the provider. In particular, the exchanger not affiliated with the provider may not have a customer account with the provider. One or more processing circuits may authenticate a relationship (e.g., husband/wife, co-habitant/co-habitant, father/son, etc.) between an exchanger affiliated with the provider and an exchanger not affiliated with the provider. For example, the processing circuits may analyze data from data source 190. The data may include, but is not limited to, personal information available on a social media network (e.g., connections, messages, profile information, etc.) or electronic records (e.g., family records, contracts, public records, etc.). In some embodiments, one or more processing circuits may use machine learning algorithms to predict the relationship between the exchanger affiliated with the provider and the exchanger not affiliated with the provider. The processing circuits may assign a prediction score in response to machine learning algorithms predicting the relationship between the exchanger affiliated with provider and the exchanger not affiliated with the provider. The processing circuits may authenticate the relationship between the exchanger affiliated with the provider and the exchanger not affiliated with the provider if the prediction score reaches a certain threshold score.

In some embodiments, alternative methods of authenticating the relationship between the first and second exchanger (e.g., when one is not affiliated with the provider) can include biometric verifications, such as fingerprint or facial recognition scans that are stored on shared devices or platforms. Another method could be the verification of shared assets or liabilities, such as jointly held property or shared financial responsibilities, which could be sourced from legal databases or credit report agencies. Additionally, multi-factor authentication techniques involving personal questions or sending authentication codes to shared addresses or contact points could also be employed to further validate the relationship between the two exchangers.

In some embodiments, the data of at least one of the first exchanger and the second exchanger may be protected. That is, the data may only be accessible by people or entities with permission to access the data (e.g., authorized users). In some embodiments, an exchanger (i.e., primary data holder) grants a plurality of secondary data holders (e.g., trusted people and entities) access to the protected data. Access to protected data may be granted through a variety of data distribution processes such as, but not limited to, encryption, API access, token-based authorization, access control lists (ACLs), role-based access control (RBAC), consent mechanisms, and so on. In some embodiments, access may be granted by a combination of one or more of said data distribution processes. Protected data may include sensitive data such as, but not limited to, social security numbers (SSN), passport number, deoxyribonucleic acid (DNA), financial account number, other personal identifying information, biometric information, geolocation data indicating one or more locations of a person, photographs of people, criminal records, credit and/or payment card numbers, health data, and so on. In particular, protected data may include performance indicators (e.g., credit scores) and activity data. In some embodiments, one or more protected data may be used to determine certain performance indicators. For example, protected data like credit history and outstanding debt may be used to calculate a credit score.

In some embodiments, the data of at least one of the first exchanger and the second exchanger may be unprotected. That is, no authorization is required by the user for people or entities (e.g., unauthorized users) to access the unprotected data. Thus, the unprotected data may be accessible to a plurality of people and entities. Unprotected data can include data not considered sensitive data. For example, unprotected data may include data that is publicly accessible (e.g., public government records, information publicly shared on a social network, information maintained in public directories, etc.). In particular, unprotected data may include performance indicators and activity data.

In some embodiments, at least one of the first exchanger and the second exchanger may be an economic invisible exchanger. In particular, an economic invisible exchanger may be a person that cannot provide or is not associated with a credit score report from a credit bureau (e.g., Equifax, Experian, and TransUnion). An economic invisible exchanger may include, but is not limited to, a person that has never borrowed from a provider, a person with a limited credit history (e.g., few loan payments), a person with few or no credit accounts, a person with a limited or no financial footprint (e.g., few reoccurring payments), and so on. In another embodiment, the credit invisible exchanger may share one or more protected and/or unprotected data objects with the processing circuits. In some embodiments, an economic invisible exchanger may also be a person with a financial record (e.g., credit history) that is not visible by a credit bureau. For example, a person from a foreign country (e.g., foreign agent) may have an account with a foreign provider (e.g., foreign financial institution) that is not visible by a local provider (e.g., local financial institution). The financial record of the economic invisible exchanger may also not be visible by a credit bureau because of third-party actions. For example, a customer account with the provider may be canceled or deactivated (e.g., fraud, cyberattack, security breach, inactivity, etc.).

In some embodiments, at least one of the first exchanger and the second exchanger can be a credit visible customer. In particular, a credit visible customer may be a person that can generate a credit score report from a credit bureau (e.g., Equifax, Experian, and TransUnion). An economic invisible exchanger may include, but is not limited to, a person that has borrowed from a provider, a person with an extensive credit history (e.g., multiple loan payments over a long period of time), a person with several credit accounts, a person with a diverse credit mix (e.g., auto loans, mortgage, personal loans, etc.), a person with a low credit utilization (e.g., not always reaching the maximum credit limit), few negative credit items (e.g., late payments, defaults, bankruptcies), a person with an extensive financial footprint (e.g., few reoccurring payments), and so on. In some embodiments, the credit visible exchanger may share one or more protected and/or unprotected data objects with one or more processors.

In some embodiments, at least one of the first exchanger and the second exchanger may be a foreign exchanger. A foreign exchanger may be affiliated with a foreign provider (e.g., foreign financial instruction) such that the foreign exchanger has an account with the foreign provider. The foreign provider may perform substantially similar functions to the provider as described above. In some embodiments, the performance indicators of the first exchanger may be determined differently from the performance indicators of the second exchanger if at least one of the first exchanger and the second exchanger is a foreign exchanger. For example, a non-foreign first exchanger may have a FICO score, but a foreign second exchanger in Germany may have a SCHUFA score. Such scores may be determined using different credit or economic metrics. In some embodiments, the activity data of the first exchanger may be determined differently from the activity data of the second exchanger if at least one of the first exchanger and the second exchanger is a foreign exchanger. For example, a non-foreign first exchanger must obtain a juris doctor degree to practice law, but a foreign second exchanger in the United Kingdom must obtain at least one of a Bachelor of Law (LLB), a Bachelor of Arts (BA), or Bachelor of Science (BSC) to practice law. Such programs may have different educational requirements. In other embodiments, the performance indicators and activity data of a foreign exchanger may be substantially similar to the activity data of a non-foreign exchanger. In additional embodiments, the foreign exchanger may share one or more protected and/or unprotected data objects with the processing circuits.

In some embodiments, at least one of the first exchanger and the second exchanger that is a foreign exchanger may also be an economic invisible exchanger. In particular, it may be difficult for non-foreign entities (e.g., providers and credit agencies) to identify the financial information (e.g., credit score, credit history, etc.) of a foreign exchanger. A foreign exchanger may also be an economic invisible exchanger for several reasons such as, but not limited to, differences in credit reporting systems (e.g., a United States credit agency accounts for a first factor, but foreign credit agency does not account for the first factor), limited access to financial information of foreign exchangers (e.g., lack of established relationships between the foreign and the United States), lack of established credit relationships (e.g., foreign exchanger is a recent credit participant in the United States), lack of a credit reporting identifier (e.g., social security number), non-residency status (e.g., foreign exchanger is not a United States citizen or not domiciled in a particular state), and so on.

At step 310, one or more processing circuits are configured to receive a selection of at least one actionable element corresponding to an activity of the first exchanger and the second exchanger. The one or more processing circuit may receive the selection of at least one actionable element through one or more inputs such as, but not limited to, a mouse input a keyboard input, a touchscreen input, voice recognition, gesture recognition, eye tracking, and so on. In some embodiments, the user selects one actionable element among a plurality of actionable elements. The one or more actionable elements may be provided via a graphical user interface (GUI) on a user device (e.g., desktop, laptop, tablet, smartphone, etc.). In some embodiments, one or more processing circuits may help a user identify which actionable element is the most relevant. For example, one or more processing circuits may produce one or more queries for a user and said one or more processing circuits may produce a recommended actionable element based on inputs provided by the user in response to the one or more queries. In some embodiments, one or more processing circuits may use machine learning to process a user's answers and help the user identify the relevant actionable element. For example, a first input in response to a first query may produce a second query, but a second input in response to the first query may produce a third query. That is, the one or more processing circuits adjusts the queries based on the user inputs.

In some embodiments, the activity can an economic or financial activity. In particular, the economic activity can be a type of joint loan the first exchanger and second exchanger attempt to obtain (e.g., car loan, mortgage, personal loan, etc.). The joint loan may be provided by the provider or a second provider (e.g., third-party financial institution). In some embodiments, the economic activity includes secondary financial information such as, but not limited to, the loan amount, the interest rate for the loan, the repayment period, and so on. One or more processing circuits may verify that the user is eligible to receive the loan by considering, among other things, identification documents (e.g., birth certificate, passport, driver's license, social security number, etc.), proof of residence, and financial information. The first exchanger and the second exchanger may jointly control an exchangeable asset (e.g., home, car, etc.) as a result of the economic activity. The exchangeable asset may be originally controlled by a third-party exchanger (e.g., bank, car dealership, etc.).

In some embodiments, instead of a joint loan, the first and second exchanger might opt for co-signing a loan, where one party agrees to assume the debt obligation if the primary borrower defaults. Additionally, they could consider alternatives like credit partnerships or entering into an agreement for shared credit accounts, which allow both parties to benefit from the credit activity without jointly borrowing. Additionally, and/or alternatively, the first and second exchanger could explore avenues like shared equity financing, where both parties contribute to the down payment of an asset and share in its appreciation or depreciation value. They might also consider joint investment accounts, pooling resources together for potential mutual financial growth. With these varied options, exchangers can use various options to collaboratively engage in financial or economic endeavors to generate an MDP score.

In some embodiments, the agreement between the first exchanger and the second exchanger as to the activity may be verified by a consensus mechanism. In some embodiments, the consensus mechanism receives a first actionable element from the first exchanger and a second actionable element from the section exchanger. Any of the first actionable element and the second actionable element may be received according to any of the embodiments described above. In some embodiments, method 300 may proceed past step 310 even if the first actionable element the second actionable element do not match. In some embodiments, method 300 may not proceed past step 310 unless the first actionable element matches the second actionable element. In such an embodiment, the secondary information of the first actionable element must also match the secondary information of the second actionable element. If the first actionable element does not match the second actionable element, modeler circuit 123 may transmit a non-consensus notice via network 130 to the first exchanger user device and the second exchanger user device. In some embodiments, an exchanger affiliated with the provider can use user client application 154 to configure their account settings to automatically proceed to the next steps of method 300 for certain actionable elements. For example, a first exchanger affiliated with a provider may enable a second exchanger to access the first exchanger's performance indicators and activity data to model a MDP score if the activity is a mortgage loan. Changes to account settings may be reflected in customer account database 180.

In some embodiments, the agreement between the first exchanger and the second exchanger as to the activity is recorded on the blockchain. For example, a new block is added on a blockchain after the activity is verified. In such embodiments, the activity can be verified via a blockchain consensus mechanism (e.g., proof of work (POW), proof of stake (POS), practical Byzantine fault tolerance (PBFT), delegated poof of stake (DPOS), etc.). In some embodiments, a plurality of activities are verified and recorded on the blockchain.

At step 315, one or more processing circuits are configured to identify a performance model based on the selection of the activity. In general, the performance model can be identified or generated based on the selection of an activity. This activity can correlate with the functions of two different entities, the first exchanger and the second exchanger. In some embodiments, the selection of the performance model from a collection of different performance models can be based on the cross-referencing of one or more activity parameters with the selected activity and at least one of the exchangers. For example, cross-referencing could include mapping the activity parameters to different models, comparing these parameters to predefined thresholds, or matching the parameters with the characteristics of the models. In some embodiments, the activity parameters could be, but are not limited to, any attributes or measurements related to the exchangers' activities, such as credit utilization rate, payment history, length of credit history, mix of credit types, and recent credit inquiries. Cross-referencing can include analyzing each exchanger's unique set of activity parameters against a database of performance models. Utilizing vector similarity measures and threshold-based filtering, the processing circuits can determine the most fitting performance model that captures the nuances of both exchangers' financial behaviors.

In some embodiments, a performance model may be identified based on the selection of a credit type. The credit type may include credit options such as, but not limited to, consumer credit (e.g., personal loans, auto loans, home loans, etc.), business credit (e.g., equipment financing, commercial mortgages, trade credit, etc.), secured credit (e.g., loan backed by collateral such as a car or home), unsecured credit (e.g., loans based on creditworthiness), revolving credit (e.g., credit card, home equity credit, retail store credit, etc.), installment credit (e.g., auto loans, mortgages, student loans, etc.), open-end credit (e.g., overdraft lines of credit), closed-end credit, and so on.

In embodiments where an exchanger does not have any credit or credit history, alternate activity parameters may be used. For example, the activity parameters could be frequency and amount of regular bill payments such as rent, utilities or phone bills, evidence of saving behavior, employment history and stability, or personal references that can vouch for the individual's reliability and responsibility. In embodiments where the exchanger is foreign and does not have a performance indicator (e.g., in the United States), activity parameters might include international credit reports, history of fulfilling financial obligations in their home country, income stability, residency status, visa type, and employment details. When evaluating exchangers without established credit scores, alternate activity parameters can offer insight into their financial behavior. Digital transactional data, encompassing e-commerce transactions like recurring subscriptions or regular online purchases, can be assimilated into an “e-commerce credit scoring” system, serving as one such activity parameter. Other activity parameters may include analysis of educational backgrounds and professional qualifications to infer potential earnings and fiscal responsibility. Furthermore, integration with fintech platforms facilitates the extraction and analysis of non-traditional financial data, refining the assessment of these exchangers.

In some embodiments, the identified or generated performance model is used for forecasting the future performance of the first exchanger and/or the second exchanger. In creating the forecasts, the performance model can take into account various factors. In some embodiments, one factor is the identified patterns or correlations with the one or more activity parameters. In particular, the processing circuits executing the model might examine how different patterns in the activity parameters, such as trends or anomalies, are associated with the exchangers' performance and activity. For example, if there's a strong correlation between an exchanger's timely bill payments and their reliability in financial transactions, this pattern could be weighted highly in predicting their future performance. In another example, an exchanger with consistent income and stable employment history might be deemed reliable, even without a credit history, and these patterns would influence the model's forecasts.

In some embodiments, another factor that the processing circuits executing the model might consider is a weighted contribution of a performance indicator, the first activity data, and the second activity data. That is, processing circuits executing the model may not treat all inputs equally but instead assigns different weights to them based on their importance or reliability. For example, where an exchanger has an excellent payment history but a short credit length, the processing circuits might assign a higher weight to the payment history as it's a stronger indicator of creditworthiness. In another example, for a foreign exchanger, the processing circuits might give more weight to their income stability and employment details domestically, rather than their international credit report, if the latter is hard to verify or not directly comparable to domestic standards.

In some embodiments, the performance model can take the form of a linear equation, which uses coefficients to weigh different activity parameters and providing an embodiment to calculate the MDP score. In some embodiments, the model could be a non-linear equation, which allows for additional interactions between the activity parameters. For example, the non-linear equation can take into account how the impact of one parameter on the score changes as the values of other parameters change. In various embodiments, the performance model could incorporate decision rules or threshold values, similar to a decision tree. In particular, this type of model can handle different scenarios and categorize the exchangers into various levels based on the combinations of their activity parameters. In some embodiments, the performance model could be a statistical model that considers uncertainty (e.g., a Bayesian model or a stochastic model). These models can measure of confidence or a range of possible scores, reflecting a potential variability or unpredictability in the exchangers' activities. Additionally, in some embodiments, the performance model could incorporate artificial intelligence (AI), generative AI (GAI), or machine learning algorithms.

At step 320, one or more processing circuits are configured to collect at least one performance indicator associated with the first exchanger or the second exchanger. In some embodiments, performance indicators are collected from private and public third parties such as, but not limited to, financial institutions (e.g., banks, credit unions, and other loan providers), credit card companies, credit bureaus, insurance companies, government agencies, and so on. For example, one or more processing circuits may collect credit card payment history from a credit card company. Performance indicators may be collected from one or more third parties because the performance indicators are maintained by one or more third parties. For example, a financial institution and a credit card company may have access to a user's credit card payment history. In other embodiments, performance indicators maintained by third parties are collected from other third parties. In such embodiments, third parties may determine (e.g., calculate) certain performance indicators based on performance indicators collected from other third parties. For example, a credit bureau may collect information such as, but not limited to, payment history, outstanding debt, length of credit history, credit mix, and existing credit lines to calculate a user's credit score, and so on. In some embodiments, collected performance indicators are stored and maintained by the provider.

Performance indicators may be collected manually or automatically. In some embodiments, performance indicators are collected from third parties in response to a data request from a requestor. The data request may include information such as, but not limited to, the type of performance indicators requested, the intended user of the requested performance indicators, and the latest date the request should be processed. The third-party may authenticate the identity of the requestor and verify that the user has authorized the requestor permission to access the user's performance indicators as part of processing the data request. In some embodiments, performance indicators are automatically collected from a third-party. In such embodiments, a user may grant certain third-parties permission to access the user's performance indicators. Performance indicators may be periodically collected from third parties after a threshold collection time has elapsed.

In some embodiments, one or more processing circuits may use machine learning to process collected performance indicators. In such embodiments, one or more processing circuit may be able to collect the performance indicators of a first user, but not the performance indicators of a second user. That is, one user may, in the interest of privacy, prevent third parties from accessing performance indicators unless such third parties are granted access to the performance indicators. In particular, one or more processing circuits may predict the performance indicators of the first user by analyzing the performance indicators of the second user, wherein the one or more processing circuits are capable of collecting the performance indicators of the second user.

At step 325, one or more processing circuits are configured to collect the first activity data of the first exchanger and the second activity data of the second exchanger. In some embodiments, activity data may be collected from a third-party (e.g., a private company, a public company, a non-profit, a government agency, etc.). For example, driving records may be collected from a statewide Department of Transportation. In another example, personal information (e.g., social activity) may be collected from a social media network. In another embodiment, the activity data may be collected automatically using collection tools such as, but not limited to, bots, web scrapers, data crawlers, data APIs, internet of things devices (IoT), sensor networks, social media listening tools, and so on. In such an embodiment, one or more collection tools may use machine learning algorithms to collect activity data. In an alternative embodiment, activity data may be manually collected by submitting data requests in a substantially similar manner as described above for performance indicators. In some embodiments, activity data may be collected from one or more third parties or activity data may be determined by third parties using one or more activity data in a substantially similar manner as described above for performance indicators. In other embodiments, activity data may be stored or maintained by the provider in a substantially similar manner as described above for performance indicators.

In some situations, the activity data is not visible to a third party. That is, the activity data cannot be collected by third-party. For example, some traffic accident history may be unreported (i.e., the report is not maintained by a statewide Department of Transportation). In some embodiments, activity data that is not maintained by a third party may be collected through self-reporting processes such as, but not limited to, email, phone lines, web forms, reporting systems, reporting portals, and so on. One or more of the self-reporting processes may involve GUIs. For example, one or more processing circuits may be configured to prompt the user to provide any relevant activity data that is not maintained by a third-party. In some embodiments, one or more processing circuits are configured to gather information from a third party to verify the veracity of an exchanger's answer. In other embodiments, one or more processing circuits may use machine learning to predict whether the exchanger's answer is correct. One or more processing circuits may assign a truthfulness score to gage the truthfulness of the exchanger's response. An untruthful response may affect an exchanger's MDP score. For example, a low truthfulness score may negatively impact (e.g., lower) an exchanger's MDP score, but a high truthfulness score may positively impact (e.g., raise) an exchanger's MDP score.

In some embodiments, collecting performance indicators and activity data may involve collecting metadata. In particular, the metadata may include the source of the data, the type of data collected, the time the data was collected, the size of the data, data access permissions, and so on. In another embodiment, collecting performance indicators and activity data may also involve collecting performance parameters. In particular, performance parameters may be the minimum data required to approve the activity. For example, the minimum information required to acquire a mortgage may be the address of the desired property while the minimum information required to acquire a car loan may be the make and model of the desired vehicle. In some embodiments, the performance parameters are collected from an exchanger via a GUI. In additional embodiments, one or more processing circuits may perform data validation and quality assurance testing to enhance the data quality. For example, the data may be cleaned to identify and correct errors, inconsistencies, and missing values in the collected data. In additional embodiments, one or more processing circuits may periodically delete performance indicators and activity data. In particular, performance indicators and activity data may be deleted to protect user privacy. For example, a data handler may delete performance indicators and activity data after a deletion threshold (e.g., a fixed number of days). In additional embodiments, the performance indicators and activity data may be securely transmitted to protect user privacy. For example, the performance indicators and activity data may be transmitted over an encrypted channel. In another example, the owner of the performance indicators and activity data may be anatomized for certain third-party data recipients so as to protect users' privacy.

One or more processing circuits may be configured to periodically update the performance indicators and activity data stored by modeling dataset 120. One or more processing circuits may compare the performance indicators and activity data stored by modeling dataset 120 with performance information stored in data source 190. In some embodiments, the performance information includes the most up to date performance indicators and activity data for each exchanger. In response to the comparison, one or more processing circuits may identify discrepancies between the performance indicators and activity data stored in modeling dataset 120 and the performance information stored in data source 190. Discrepancies may include new event entries (e.g., new payments, new accident reports, new criminal reports, etc.) for the respective performance indicator or activity data. If the performance indicators and the activity data stored in modeling dataset 120 are different from the performance information stored in data source 190, one or more processing circuits may initiate an update sequence. The update sequence may involve retrieving the most up to date performance indicators and activity data from data source 190 and overwriting the older performance indicators and activity data stored in modeling dataset 120 with the newer performance indicators and activity data. Thus, discrepancies in performance indicators and activity data arise from data entry errors, delays in updating, changes in data standards, or potential fraud. When detected, the processing circuits analyze the cause. For example, a recently cleared debt not reflected might improve an exchanger's MDP score once updated, but suspected fraudulent data requires additional verification before incorporating.

At step 330, one or more processing circuits are configured to model the at least one performance indicator, the first activity data, and the second activity data to generate a multi-dimensional performance (MDP) score. The MDP score can be used for a variety of joint activities, including car loans, mortgages, and other activities that involve co-exchangers. In some embodiments, the MDP score is recognized by financial institutions (e.g., banks) that are involved in such activities. In particular, the MDP score may increase the likelihood of approval of the economic activity (e.g., loan) by a financial institution. That is, the MDP score can be measured on a scale and a higher score increases the likelihood of approval of the economic activity. For example, a first exchanger and a second exchanger may have a high MDP score (e.g., the first exchanger and the second exchanger are in the 80^{th} percentile of customers with MDP scores) and this high MDP score may mean that the first exchanger and the second exchanger are more likely to obtain a loan (e.g., car loan or mortgage) than a third exchanger and a fourth exchanger with a low MDP score (e.g., 20^{th} percentile of customers with MDP scores). In some embodiments, the MDP score may increase the likelihood of approval of the economic activity as compared to using the at least one performance indicator and activity data of at least the first exchanger or second exchanger. That is, a first exchanger and a second exchanger may be more likely to receive approval for an economic activity because the MDP score for the first exchanger and the second exchanger is higher than the individual MDP scores of either the first exchanger or the second exchanger.

In some embodiments, the process of modeling can include using techniques such as machine learning, statistical analysis, and pattern recognition to establish relationships between different data points and predict future outcomes based on those relationships. In some embodiments, modeling can begin with the selection of an appropriate model based on the type of data and the specific predictions that need to be made. In some embodiments, the processing circuits can utilize pattern recognition methodologies to identify trends and to generate an MDP score. For example, pattern recognition applied to user activity data and performance indicators can discern cyclical trends in expenditure, identifying increases at the beginning and middle of the month with a decline towards the end. By integrating this trend with performance indicators, like credit scores, the processing circuits can generate an MDP score. This structure can anticipate that one or more exchangers with higher credit scores are likely to maintain a steady spending pace throughout the forthcoming month, whereas those with lower scores may exhibit amplified cyclical variations in future spending patterns. In another example, spectral analysis can be utilized to analyze the frequency components embedded within a user's transaction history. By updating time-centric transaction data into a frequency-centric portrayal, dominant financial behaviors, marked by recurrent spending frequencies, can become discernible. Correlating this with a performance indicator, such as the debt-to-income ratio, the user data structure can extrapolate that individuals with superior ratios might display more regularized spending behaviors in the near future, marked by fewer pronounced cyclical deviations. In yet another example, linear regression models might be selected by the processing circuits for predicting continuous outcomes such as the amount a user might spend on their credit card, while logistic regression models might be selected for predicting binary outcomes such as whether a user will make a car loan payment on time or not. It should be understood that the term modeling herein encompasses a wide range of techniques and approaches aimed at understanding patterns within data and predicting future outcomes (i.e., using an MDP score). This could include anything from statistical methods and rule-based systems to machine learning algorithms, depending on the nature of the data and the specific predictions to be made by the processing circuits. Thus, modeling involves selecting techniques based on the specific characteristics of the data, ensuring that the chosen method or methods accurately captures patterns and predicts user activities.

In some embodiments, the model parameters can be trained and optimized using the cleaned, classified, and linked user activity data and performance indicators. This training process can include using algorithms to adjust the model parameters such that the error between the model's predictions and the actual outcomes is minimized. The modeling process can also include feature engineering, which is the process of creating new features or modifying existing ones to improve the model's predictive power. For example, instead of using raw transaction amounts, a feature representing the average transaction amount over a certain period might be more predictive of a user's future economic activity.

Once one or more models or techniques are trained and/or optimized, the processing circuits can use the model to generate an MDP score that corresponds to future activities of the user. This MDP score can be a mathematical representation, a decision tree, a set of rules, or any other structure that captures the relationships between different data points and can be used to make predictions about future activities of multiple exchangers. In some embodiments, the MDP score can then be used to predict a wide range of future economic activities associated with a line of credit, such as paying a credit card bill, making a car loan payment, applying for a new loan, or even defaulting on a loan. In some embodiments, the MDP score can be utilized to forecast future economic activities related to a mortgage, such as timely monthly payments or potential refinancing scenarios. In some embodiments, the MDP score might predict behaviors tied to personal loans, encompassing aspects like early repayments, potential loan extensions, or seeking additional borrowing. Over time, as more user activity data and performance indicators are collected, the model can be retrained and updated to reflect the most recent patterns in the data. Moreover, the modeling process can include various safeguards to ensure privacy and security of user data (e.g., anonymizing the data).

In some embodiments, generating a MDP score may involve pre-processing the at least one performance indicator, the first activity data, and the second activity data. In particular, preprocessing the data may involve processes such as, but not limited to, removing duplicates, replacing missing values, normalizing or scaling features, formatting and encoding the data, and splitting the data into training and test sets, and so on. In additional embodiments, the performance indicators and activity data are organized based on relevant modeling features. In particular, organizing performance indicators and activity data may involve processes such as, but not limited to, correlation analysis, feature importance ranking, dimensionality reduction methods (e.g., Principal Component Analysis and Linear Discriminant Analysis), and so on.

In some embodiments, modeling the at least one performance indicator, the first activity data, and the second activity data may involve identifying one or more statistical relationships associated with at least one of the first exchanger or second exchanger. In particular, identifying one or more statistical relationships may involve analyzing the connection between performance indicators and activity data and activity outcomes (e.g., whether or not the exchangers received a loan, such as a car loan or mortgage, from a financial institution). For example, one or more processing circuits may establish a positive correlation between fraudulent activity and negative activity outcomes (e.g., loan refusals). Furthermore, one or more processing circuit may analyze how certain performance indicators and activity data affect the MDP score, wherein the MDP score may be related to the activity outcome. In additional embodiments, one or more processing circuits may identify dependency events associated with one or more performance indicators and activity data. In particular, a dependency event may simultaneously affect the results of one or more performance indicators and activity data. For example, identity theft may harm an exchanger's professional reputation and cause an exchanger to have a lower credit score.

In some embodiments, the performance model may convert each of the at least one performance indicator, the first activity data, and the second activity data into a MDP subscore. In particular, one or more processing circuits may convert the qualitative data to quantitative data (e.g., MDP subscore). One or more processing circuits may also convert quantitative data of a first form to quantitative data of a second form (e.g., MDP subscore). Converting the qualitative data and the quantitative data may involve conversion tools (e.g., mathematical algorithms). The MDP subscore for each performance indicator and activity data may be determined based on a set of subfactors specific to each performance indicator and activity data. Subfactors may include, but are not limited to, economic relevance (e.g., the extent to which the performance indicator of activity data affects a user's ability to receive a loan), history (e.g., possible changes to the performance indicators and activity data over time), trustworthiness (e.g., the extent to which the performance indicators or activity data reflects a user's ability to repay a loan), and so on. The relevant subfactors for each performance indicator and activity data may affect each MDP subscore differently. For example, a history of delinquent payments may have a substantial effect (e.g., dramatically raise or lower the MDP subscore) on a first performance MDP subscore based on credit history, but a history of parking tickets may have an insubstantial effect (e.g., minimally raise or lower the MDP subscore) on a first activity data MDP subscore based on driving history. In some embodiments, each MDP subscore is normalized to a standardized MDP subscore. Normalization techniques may include, but are not limited to, min-max normalization, z-score normalization, sigmoid normalization, and so on.

In some embodiments, the performance model may assign a performance score weight (PSW) to the at least one performance indicator, the first activity data, and the second activity data as described above. For example, a first performance indicator for a first exchanger may have a PSW of 0.50 (i.e., 50% of the MDP score is based on the first performance indicator), a first activity data for a first exchanger may have a PSW of 0.30 (i.e., 30% of the MDP score is based on the first activity data), and a second activity data for a second exchanger may have a PSW of 0.20 (i.e., 20% of the MDP score is based on the second activity data). The PSW is based on a plurality of risk assessment factors as described above. In some embodiments, one or more processing circuits are configured to generate a plurality of PSW scores for a plurality of performance indicators and activity data. For example, a first performance indicator for a first exchanger may have a PSW of 0.10 (i.e., 10% of the MDP score is based on the first performance indicator), a second performance indicator for a first exchanger may have a PSW of 0.40 (i.e., 40% of the MDP score is based on the second performance indicator), a first activity data for a first exchanger may have a PSW of 0.10 (i.e., 10% of the MDP score is based on the first activity data), a second activity data for a second exchanger may have a PSW of 0.20 (i.e., 20% of the MDP score is based on the second activity data), and a third activity data for a second exchanger may have a PSW of 0.20 (i.e., 20% of the MDP score is based on the third activity data). In some embodiments, the PSWs associated with the first exchanger are aggregated to generate a first contribution score and the PSWs associated with the second exchanger are aggregated to generate a second contribution score. The first contribution score represents the first exchanger's contribution to the MDP score and the second contrition score represents the second exchanger's contribution to the MDP score.

The MDP score may be updated (e.g., calculated). In some embodiments, the MDP score is calculated via a weighted sum. In particular, each MDP subscore may be multiplied by a corresponding PSW to generate a plurality of weighted MDP subscores. Then, the plurality of weighted MDP subscores are aggregated to generate a MDP score. It should be understood, however, that other methods and processes may be used to generate a MDP score. One or more processing circuits may execute one or more mathematical processes to calculate a MDP score such as, but not limited to, weighted sum, linear combination, Bayesian networks, scoring models (e.g., machine learning algorithms), similarity measures (e.g., Jaccard similarity and Euclidean distance), rank aggregation, statistical methods (e.g., regression analysis and principal component analysis), optimization algorithms (e.g., linear programming and integer programming), rule-based systems, composite scoring, and so on.

In some embodiments, the performance model may use machine learning to determine the MDP score. In particular, the performance model may create a customer profile for a user and predict the user's MDP score based on the customer profile. The customer profile may include information such as, but not limited to, the activity request, performance indicators, activity data, and so on. The performance model may compare the customer profile with a plurality of customer profiles associated with a plurality of other users, wherein the plurality of customer profiles associated with a plurality of other users is part of a training dataset. The performance model identifies similar users based on the customer profile and predicts a MDP score based on similar customer profiles. The performance model may compare the predicted MDP score against a true MDP score that is part of a validation dataset. In particular, the performance model may compare the MDP score against the true MDP score using comparison metrics such as, but not limited to, mean square error (MSE), mean absolute error (MAE), coefficient of determination (i.e., R-squared), and so on. In some embodiments, parameters and hyperparameters of the performance model may be adjusted to improve prediction performance.

In some embodiments, the least of the first exchanger or the second exchanger may require (or it may be suggested) a third-party exchange sponsor. One or more processing circuits may determine whether the exchanger requires a third-party exchange sponsor. In particular, one or more processing circuits may analyze sponsor factors such as, but not limited to, credit history, credit score, income, collateral, employment, and so on. In some embodiments, the third-party exchange sponsor is a cosigner for the activity (e.g., mortgage, car loan, student loan, etc.). The cosigner may include a spouse, a co-habitant, a parent, or a friend. In some embodiments, the MDP score is based on the performance indicators and activity data of a cosigner. One or more processing circuits may use the performance model to model the cosigner's performance indicators and activity data in a similar manner as described above for the performance indicators and activity data of the first exchanger and the second exchanger.

In some embodiments, one or more processing circuits may require more data (e.g., performance indicators, activity data, activity parameters, performance parameters, etc.) to generate a MDP score. That is, a MDP score can only be generated if a data threshold (i.e., a minimum amount of data required to generate a MDP score) is satisfied. In some embodiments, one or more processing circuits may allow exchangers to generate a MDP score even if the data threshold is not satisfied. In such an embodiment, one or more processing circuits may notify the exchangers that the MDP score may not be an accurate representation of creditworthiness. In additional embodiments, one or more processing circuits may generate a confidence score based on the MDP score, wherein the confidence score measures the likelihood that the exchangers will be approved for an economic activity (e.g., a loan). In such an embodiment, the confidence score may be related to the performance indicators and activity data (e.g., the type and amount of performance indicators and activity data). In an alternative embodiment, the confidence score may be predicted based on machine learning.

In some embodiments, the processing circuits can use rule-based systems to model the user activity data of multiple exchangers and performance indicators. Rule-based systems can be where predefined rules are created by the processing circuits (or domain experts) to infer outcomes based on given conditions. For example, if one or more exchangers consistently makes credit card payments in full before the due date, a rule might state that the exchanger(s) is likely to do the same in the future. This rule can then be applied to the exchanger's data to predict their future activity of making a credit card payment. In some embodiments, the processing circuits can use statistical methods for modeling. This can involve approaches like time series analysis or trend analysis. For example, time series analysis can be used to identify patterns in the user's past activity data, such as seasonal trends, cyclical patterns, or overall growth trends. If an exchanger consistently increases their credit card spending during the holiday season, time series analysis can identify this pattern and predict a similar increase for the next holiday season. Trend analysis, on the other hand, can be used to identify long-term changes in the exchanger's activity data. For example, if the MDP score has been steadily improving over several years, trend analysis can project this trend into the future and predict a continued improvement in the MDP score.

Accordingly, the processing circuits can use a predictive modeling approach to generate an MPD score. Additionally, the modelling approach operates agnostically of the financial institution providing the service, offering an integrated and full view of an aggregated or combined financial commitments of the exchangers. Furthermore, the predictive modeling approach executed by the processing circuits can detect seasonal or event-based patterns in the exchanger's spending and behaviors (sometimes referred to herein as “characteristics”). If, for example, the two exchangers typically increase credit card spending during holiday seasons, the model can anticipate higher bill amounts during these periods.

At step 335, one or more processing circuits are configured to provide the MDP score. The MDP score is provided to the least of the first exchanger and the second exchanger in response to modeling the at least one performance indicator, the first activity data, and the second activity data to generate a MDP score. In some embodiments, the MDP score is provided via a direct message (e.g., text message, email, fax, etc.). In particular, the direct message may be received on a user device (e.g., smartphone, desktop, laptop, tablet, etc.). One or more processing circuits on user device may produce a notification on said user device indicating that a MDP score has been generated. In some embodiments, the MDP score is provided via a GUI. In particular, the GUI may be displayed on a user device.

Referring now to FIG. 4A, a user device for modeling an MDP score with modeler system 100 of FIG. 1 is shown according to an example embodiment. As shown, user device 140 has user interface 400. User interface 400 may include the MDP score. The MDP score may be reported in a variety of forms such as, but not limited to, a numerical value, a rating, a percentage, and so on. User interface 400 may include model element 402 (e.g., a button or another interactable/actionable element) for modeling and/or remodeling a MDP score. That is, selecting model element 402 allows the user to model and/or remodel a MDP score, wherein the MDP score is visible to the user on user interface 400. In some embodiments, user interface 400 may include the individual contributions of the first exchanger and the second exchanger. In particular, user interface 400 may include the first contribution score of the first exchanger and the second contribution score of the second exchanger. The first exchanger and the second exchanger may have different or similar financial characteristics. In FIG. 4, for example, the first exchanger and the second exchanger are visible exchangers. In some embodiments, user interface 400 may include the confidence score of the exchangers. In some embodiments, one or more of the information shown on user interface 400 may be provided by a GUI.

In some embodiments, user interface 400 may include a score analysis of the MDP score. The score analysis of the MDP score on user interface 400 may include an explanation of how the performance model calculated the MDP score. For example, user interface 400 may include an analysis of how factors such as performance indicators and activity data affected the MDP score calculation, wherein said analysis may further include a breakdown of the MDP subscores or PSWs for each performance indicator or activity data. In another example, user interface 400 may describe the methods and processes (e.g., mathematical calculations) used to calculate the MDP score. In some embodiments, the score analysis of the MDP score on user interface 400 may include a comparison section. The comparison section may compare a score report of a group comprising the first exchanger and the second exchanger with a plurality of score reports of other groups comprising a plurality of exchangers. The comparison section may include information such as, but not limited to, a percentile ranking (e.g., the percentage of MDP scores that are lower than a certain MDP score), a historical analysis (e.g., how a certain MDP score compares to other MDP scores over a period of time), and MDP subscore and PSW comparisons, and so on.

In some embodiments, the score analysis on user interface 400 may include an MDP rating. In particular, the MDP rating helps the first exchanger and the second exchanger interpret the MDP score. For example, a low MDP score may be associated with a MDP rating of “Bad” while a high MDP score may be associated with MDP rating of “Good.” In some embodiments, the score analysis of the MDP score on user interface 400 may include one or more performance ratings. In particular, a performance rating may be associated with scoring group, wherein the scoring group comprises one or more performance indicators and activity data that have one or more common characteristics (e.g., financial information, transactional information, personal information, etc.). For example, a first scoring group may have an A+ performance rating, but a second scoring group may have a B− performance rating.

Referring now to FIG. 4B, a user device for modeling an MDP score with modeler system 100 of FIG. 1 is shown according to another example embodiment. In particular, user interface 400 may show the contribution scores of a visible first exchanger (e.g., 52, 2A, and 72) and an invisible second exchanger (e.g., ?). In some embodiments, at least one of the first exchanger and the second exchanger may have a plurality of contribution scores. Such contribution scores may arise from a plurality of performance indicators and activity data. In another embodiment, at least one of the first exchanger and the second exchanger may not have a contribution score. Such a result may arise if there is not enough information (e.g., performance indicators and/or activity data) to generate a MDP score. In some embodiments, user interface 400 may also include the score analysis of the MDP score and its corresponding features as described above.

In one example, consider Lisa and Mark, applying for a joint loan. On the user interface 400, Lisa, the first visible exchanger, shows varied contribution scores: 52 derived from her creditworthiness in previous financial transactions, 2A as a score resulting from her consistent digital transaction behavior in online marketplaces, and 72 based on her employment stability and consistent income. Mark, as the invisible second exchanger, displays a “?” indicating that his credit history or other relevant data might not be available or sufficient for a discernable contribution score. Additionally, the score “2A” on a scale from 1A to 5A might indicate an alternate activity parameter, such as Lisa's transactional reliability in non-traditional financial platforms or digital marketplaces. Given their combined data, the modeler system calculates their MDP score. Incorporating both Lisa's diverse credit metrics and any available non-traditional data or activity parameters for Mark, their collective MDP score is determined to be 59.

Referring now to FIG. 4C, a user device for providing options to optimize an MDP score is shown according to an example embodiment. As shown, user interface 400 may include first exchanger score amplification element 404, second exchanger score amplification element 406, and combined score amplification element 408. In some embodiments, the elements of FIG. 4C (i.e., first exchanger score amplification element 404, second exchanger score amplification element 406, and combined score amplification element 408) may be generated on user interface 400 in response to modeling a MDP score. First exchanger score amplification element 404, second exchanger score amplification element 406, and combined score amplification element 408 may be selected to generate a corresponding amplification analysis (not shown in FIG. 4C).

Referring now to FIG. 4D, a user device for providing an amplification analysis of a MDP score is shown according to example embodiments. As show, user interface 400 may include first amplifier action element 410, second amplifier action element 412, first performance indicator group 414, second performance indicator group 416, third performance indicator group 418, first MDP group 420, second MDP group 422, and third MDP group 424. In some embodiments, the elements of user interface 400 in FIG. 4D may be generated in response to selecting one of the amplification elements (i.e., first exchanger score amplification element 404, second exchanger score amplification element 406, and combined score amplification element 408). That is, user interface 400 may change based on the selected amplification element. For example, user interface 400 may show an amplification analysis of the first exchanger in response to selecting first exchanger score amplification element 404, but user interface 400 may show the combined amplification analysis of both exchangers in response to selecting combined score amplification element 408. It should also be understood that user interface 400 is not limited to the elements shown in FIG. 4. In some embodiments, user interface 400 may include a plurality of amplifier actions, performance indicator groups, and MDP groups.

In some embodiments, first amplifier action element 410 and second amplifier action element 412 generate corresponding amplifier actions. The amplifier action elements may help the one or more exchangers improve their financial trustworthiness (e.g., creditworthiness). In particular, the amplifier actions may help the one or more exchangers improve their MDP score or their MDP subscore. In some embodiments, selecting an amplifier action element (e.g., first amplifier action element 410 or second amplifier action element 412) may automatically initiate one or more amplifier actions that improve the MDP subscore and/or the MDP score. For example, selecting first amplifier action element 410 may cause the first exchanger to close a secondary financial account (e.g., a credit account). In another embodiment, selecting an amplifier action element may allow the exchanger to specify the parameters of the amplifier action. For example, selecting second amplifier action element 412 may allow the second exchanger to specify a spending limit (i.e., a maximum amount of money the exchanger can spend each credit cycle).

In some embodiments, selecting an amplifier action may generate a list of recommendations the first exchanger and/or the second exchanger can take to improve the MDP subscore and/or the MDP score, wherein the recommendations are generated by one or more processing circuits. In some embodiments, the recommendations may include a first recommendation for the first exchanger, a second recommendation for the second exchanger, and a combined recommendation for the first exchanger and the second exchanger. The recommendation (e.g., first recommendation, second recommendation, combined recommendation, etc.) may include proposed actions for improving the MDP score such as, but not limited to, actions to improve financial stability (e.g., strategies for minimizing debt and improving income), actions to improve trustworthiness (e.g., strategies for improving reputation), actions to improve financial aptitude (e.g., strategies for increasing education level), and so on. In some embodiments, the recommendation may provide a list of providers (e.g., financial institutions) that facilitate economic activities (e.g., loans). In particular, the list of providers may be organized and/or ranked based on the MDP score and the confidence score. In some embodiments, one or more processing circuits use machine learning to generate recommendations.

For the first recommendation aimed at the first exchanger, actions might focus on addressing specific financial gaps, such as consolidating outstanding debts or attending financial literacy seminars to boost their financial aptitude. For example, if the first exchanger has multiple high-interest credit card debts, the recommendation could advise on exploring options for debt consolidation with a lower interest rate, or taking online courses to understand better debt management techniques. Regarding the second recommendation for the second exchanger, it might center on reinforcing their trustworthiness in financial commitments. This could involve timely bill payments, enrolling in automatic payment setups to avoid late fees, or seeking out platforms where positive financial behaviors can be reported and recognized, ensuring a bolstered financial reputation. Lastly, the combined recommendation for both exchangers may promote joint strategies, such as attending partnered financial planning sessions, jointly investing in assets that appreciate in value, or establishing joint accounts with overdraft protection to minimize risks associated with financial mishaps, fostering a united approach to achieving financial stability.

Still referring to FIG. 4D, user interface 400 may include visual displays. Visual displays may include visual aids such as, but not limited to, graphs, diagrams, plots, charts, figures, and so on. In some embodiments, information used to generate the MDP subscore and/or the MDP score (e.g., activity data, performance indicators, PSWs) may be included in one or more visual displays. In other embodiments, the MDP subscore and/or the MDP scores are included in one or more visual displays. For example, FIG. 4D includes a graph illustrating how values associated with performance indicators (e.g., MDP subscores) change over time. First performance indicator group 414 illustrates how the values associated with a performance indicator change over time in response to a first amplifier action. Second performance group 416 illustrates how values associated with a performance indicator change over time in response to a second amplifier action. And third performance indicator group 418 shows how the values associated with a performance indicator change over time in response to a combination of the first amplifier action and the second amplifier action. In another example, FIG. 4D includes a graph illustrating how the MDP score changes over time. First MDP group 420 shows how the MDP score changes over time in response to the first amplifier action. Second MDP group 422 shows how the MDP score changes over time in response to the second amplifier action. And third MDP group 424 shows how the MDP score changes over time in response to the combination of the first amplifier action and the second amplifier action.

In some embodiments, the user interface 400 may include a plurality of visual displays for a plurality of information (e.g., performance indicators, activity data, PSWs, MDP subscore, MDP scores, and so on). The visual displays may illustrate the relationship between information and other variables (e.g., time, credit, savings, debt, and so on). The relationship between information and variables may be illustrated in a variety of visual displays such as, but not limited to, scatter plots, line charts, bar charts, pie charts, network diagrams, bubble charts, chord diagrams, Sankey diagrams, tree maps, radar charts, 3D plots, and so on. In some embodiments, the relationship between information and variables may be illustrated using a combination of audio and/or audiovisual elements. For example, user interface 400 may include a video that explains how the MDP score changes over time in response to the first amplifier action.

While this specification contains many specific implementation details and/or arrangement details, these should not be construed as limitations on the scope of any disclosure or of what may be claimed, but rather as descriptions of features specific to particular implementations and/or arrangements of the systems and methods described herein. Certain features that are described in this specification in the context of separate implementations and/or arrangements can also be implemented and/or arranged in combination in a single implementation and/or arrangement. Conversely, various features that are described in the context of a single implementation and/or arrangement can also be implemented and arranged in multiple implementations and/or arrangements separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Additionally, features described with respect to particular headings may be utilized with respect to and/or in combination with illustrative arrangement described under other headings; headings, where provided, are included solely for the purpose of readability and should not be construed as limiting any features provided with respect to such headings.

Similarly, while operations are depicted in the drawings in a particular order, this should not be understood as requiring that such operations be performed in the particular order shown or in sequential order, or that all illustrated operations be performed, to achieve desirable results. In some cases, the actions recited in the claims can be performed in a different order and still achieve desirable results. In addition, the processes depicted in the accompanying figures do not necessarily require the particular order shown, or sequential order, to achieve desirable results.

In certain circumstances, multitasking and parallel processing may be advantageous. Moreover, the separation of various system components in the implementations and/or arrangements described above should not be understood as requiring such separation in all implementations and/or arrangements, and it should be understood that the described program components and systems can generally be integrated together in a single software product or packaged into multiple software products.

Having now described some illustrative implementations, implementations, illustrative arrangements, and arrangements it is apparent that the foregoing is illustrative and not limiting, having been presented by way of example. In particular, although many of the examples presented herein involve specific combinations of method acts or system elements, those acts, and those elements may be combined in other ways to accomplish the same objectives. Acts, elements and features discussed only in connection with one implementation and/or arrangement are not intended to be excluded from a similar role in other implementations or arrangements.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations and/or arrangements consisting of the items listed thereafter exclusively. In one arrangement, the systems and methods described herein consist of one, each combination of more than one, or all of the described elements, acts, or components.

Any references to implementations, arrangements, or elements or acts of the systems and methods herein referred to in the singular may also embrace implementations and/or arrangements including a plurality of these elements, and any references in plural to any implementation, arrangement, or element or act herein may also embrace implementations and/or arrangements including only a single element. References in the singular or plural form are not intended to limit the presently disclosed systems or methods, their components, acts, or elements to single or plural configurations. References to any act or element being based on any information, act or element may include implementations and/or arrangements where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

Any arrangement disclosed herein may be combined with any other arrangement, and references to “an arrangement,” “some arrangements,” “an alternate arrangement,” “various arrangements,” “one arrangement” or the like are not necessarily mutually exclusive and are intended to indicate that a particular feature, structure, or characteristic described in connection with the arrangement may be included in at least one arrangement. Such terms as used herein are not necessarily all referring to the same arrangement. Any arrangement may be combined with any other arrangement, inclusively or exclusively, in any manner consistent with the aspects and arrangements disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The systems and methods described herein may be embodied in other specific forms without departing from the characteristics thereof. Although the examples provided herein relate to controlling the display of content of information resources, the systems and methods described herein can include applied to other environments. The foregoing implementations and/or arrangements are illustrative rather than limiting of the described systems and methods. Scope of the systems and methods described herein is thus indicated by the appended claims, rather than the foregoing description, and changes that come within the meaning and range of equivalency of the claims are embraced therein.

It should be understood that no claim element herein is to be construed under the provisions of 35 U.S.C. § 112 (f) unless the element is expressly recited using the phrase “means for.”

As used herein, the term “circuit” may include hardware structured to execute the functions described herein. In some embodiments, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors. In some embodiments, a circuit may take the form of one or more analog circuits, electronic circuits (e.g., integrated circuits (IC), discrete circuits, system on a chip (SOC) circuits), telecommunication circuits, hybrid circuits, and any other type of “circuit.” In this regard, the “circuit” may include any type of component for accomplishing or facilitating achievement of the operations described herein. For example, a circuit as described herein may include one or more transistors, logic gates (e.g., NAND, AND, NOR, OR, XOR, NOT, XNOR), resistors, multiplexers, registers, capacitors, inductors, diodes, wiring.

The “circuit” may also include one or more processors communicatively coupled to one or more memory or memory devices. In this regard, the one or more processors may execute instructions stored in the memory or may execute instructions otherwise accessible to the one or more processors. In some embodiments, the one or more processors may be embodied in various ways. The one or more processors may be constructed in a manner sufficient to perform at least the operations described herein. In some embodiments, the one or more processors may be shared by multiple circuits (e.g., circuit A and circuit B may comprise or otherwise share the same processor which, in some example embodiments, may execute instructions stored, or otherwise accessed, via different areas of memory). Alternatively, or additionally, the one or more processors may be structured to perform or otherwise execute certain operations independent of one or more co-processors. In other example embodiments, two or more processors may be coupled via a bus to enable independent, parallel, pipelined, or multi-threaded instruction execution. Each processor may be implemented as one or more general-purpose processors, application specific integrated circuits (ASICs), field programmable gate arrays (FPGAs), digital signal processors (DSPs), or other suitable electronic data processing components structured to execute instructions provided by memory. The one or more processors may take the form of a single core processor, multi-core processor (e.g., a dual core processor, triple core processor, quad core processor), microprocessor. In some embodiments, the one or more processors may be external to the apparatus, for example the one or more processors may be a remote processor (e.g., a cloud based processor). Alternatively, or additionally, the one or more processors may be internal and/or local to the apparatus. In this regard, a given circuit or components thereof may be disposed locally (e.g., as part of a local server, a local computing system) or remotely (e.g., as part of a remote server such as a cloud based server). To that end, a “circuit” as described herein may include components that are distributed across one or more locations.

An exemplary system for implementing the overall system or portions of the embodiments might include a general purpose computing devices in the form of computers, including a processing unit, a system memory, and a system bus that couples various system components including the system memory to the processing unit. Each memory device may include non-transient volatile storage media, non-volatile storage media, non-transitory storage media (e.g., one or more volatile and/or non-volatile memories), etc. In some embodiments, the non-volatile media may take the form of ROM, flash memory (e.g., flash memory such as NAND, 3D NAND, NOR, 3D NOR), EEPROM, MRAM, magnetic storage, hard discs, optical discs, etc. In other embodiments, the volatile storage media may take the form of RAM, TRAM, ZRAM, etc. Combinations of the above are also included within the scope of machine-readable media. In this regard, machine-executable instructions comprise, for example, instructions and data which cause a general purpose computer, special purpose computer, or special purpose processing machines to perform a certain function or group of functions. Each respective memory device may be operable to maintain or otherwise store information relating to the operations performed by one or more associated circuits, including processor instructions and related data (e.g., database components, object code components, script components), in accordance with the example embodiments described herein.

It should also be noted that the term “input devices,” as described herein, may include any type of input device including, but not limited to, a keyboard, a keypad, a mouse, joystick or other input devices performing a similar function. Comparatively, the term “output device,” as described herein, may include any type of output device including, but not limited to, a computer monitor, printer, facsimile machine, or other output devices performing a similar function.

Any foregoing references to currency or funds are intended to include fiat currencies, non-fiat currencies (e.g., precious metals), math-based currencies (often referred to as cryptocurrencies), and central bank digital currency (often referred to as CBDC). Examples of math-based currencies include Bitcoin, Ethereum, Litecoin, Dogecoin, and the like.

It should be noted that although the diagrams herein may show a specific order and composition of method steps, it is understood that the order of these steps may differ from what is depicted. For example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative embodiments. Accordingly, all such modifications are intended to be included within the scope of the present disclosure as defined in the appended claims. Such variations will depend on the machine-readable media and hardware systems chosen and on designer choice. It is understood that all such variations are within the scope of the disclosure. Likewise, software and web implementations of the present disclosure could be accomplished with standard programming techniques with rule-based logic and other logic to accomplish the various database searching steps, correlation steps, comparison steps and decision steps.

What is claimed is:

1. A system, comprising:
a processing circuit comprising memory and one or more processors, the processing circuit configured to:
authenticate a first exchanger and a second exchanger, wherein at least one of the first exchanger or the second exchanger is associated with a provider;
receive a selection of at least one actionable element corresponding to an activity of the first exchanger and the second exchanger;
identify a performance model based on the selection of the activity;
collect at least one performance indicator associated with the first exchanger or the second exchanger;
collect first activity data of the first exchanger and second activity data of the second exchanger;
model, using the performance model, the at least one performance indicator, the first activity data, and the second activity data to generate a multi-dimensional performance (MDP) score; and
provide, by the processing circuit, the MDP score.

2. The system of claim 1, wherein modeling the at least one performance indicator, the first activity data, and the second activity data comprises:
analyzing the collected performance indicator, the first activity data, and the second activity data to identify one or more patterns or correlations associated with at least one of the first exchanger or the second exchanger;
generating the MDP score utilizing the performance model to forecast future performance of both the first exchanger and the second exchanger based at least on one of (1) identified one or more patterns or correlations with one or more activity parameters, or (2) a weighted contribution of the performance indicator, the first activity data, and the second activity data.

3. The system of claim 2, wherein the processing circuit is further configured to:
store the at least one performance indicator, the first activity data, and the second activity data in a modeling dataset;
retrieve the at least one performance indicator, the first activity data, and the second activity data from the modeling dataset in response to the selection of at least one actionable element;
compare the at least one performance indicator, the first activity data, and the second activity data stored in the modeling dataset with performance information stored in a data source;
identify discrepancies between the at least one performance indicator, the first activity data, and the second activity data stored in the modeling dataset and the performance information stored in the data source; and
update the at least one performance indicator, the first activity data, and the second activity data in response to an update sequence, wherein the update sequence is initiated in response to identifying discrepancies between the at least one performance indicator, the first activity data, and the second activity data stored in the modeling dataset and the performance information stored in the data source.

4. The system of claim 1, wherein the modelling by the processing circuit using the performance model comprises:
generating a MDP subscore for each of the at least one performance indicator, the first activity data, and the second activity data;
assigning a performance score weight (PSW) to each of the at least one performance indicator, the first activity data, and the second activity data, wherein the PSW is based on a plurality of risk assessment factors;
updating each MDP subscore of the at least one performance indicator, the first activity data, and the second activity data, wherein updating each MDP score includes scaling each MDP score by the corresponding PSW to generate a plurality of weighted MDP subscores; and
aggregating the plurality of weighted MDP subscores.

5. The system of claim 1, wherein the performance model of a plurality of performance models is identified based on cross-referencing one or more activity parameters with the activity and at least one of the first exchanger or the second exchanger.

6. The system of claim 1, wherein the first exchanger is a visible exchanger to the processing circuit and the second exchanger is an invisible exchanger to the processing circuit, wherein the visible exchanger shares (1) the at least one performance indicator and (2) at least two protected data objects with the processing circuit, and wherein the invisible exchanger shares at least one of (1) unprotected data or (2) at least one protected data object with the processing circuit, wherein the unprotected data is accessible to an unauthorized user.

7. The system of claim 1, wherein the first exchanger is a visible exchanger to the processing circuit and the second exchanger is a foreign exchanger to the processing circuit, wherein the visible exchanger shares (1) the at least one performance indicator and (2) at least one protected data object with the processing circuit, and wherein the invisible exchanger shares (1) at least one foreign performance indicator and (2) at least one foreign protected data object with the processing circuit.

8. The system of claim 1, wherein the first exchanger is a first invisible exchanger to the processing circuit and the second exchanger is a second invisible exchanger to the processing circuit, wherein the first invisible exchanger shares at least one of (1) unprotected data or (2) at least one protected data object with the processing circuit, wherein the unprotected data is accessible to an unauthorized user, and wherein the second invisible exchanger shares at least one of (1) additional unprotected data or (2) at least one additional protected data object with the processing circuit.

9. The system of claim 1, wherein the processing circuit is further configured to:
generate and provide a graphical user interface comprising a plurality of future action recommendations to increase the MDP score, wherein the plurality of future action recommendations comprises (1) a first recommendation to increase the MDP score associated with the first exchanger, (2) a second recommendation to increase the MDP score associated with the second exchanger, and (3) a combined recommendation to increase the MDP score associated with both the first exchanger and the second exchanger, and wherein the actionable element is provided on the GUI.

10. The system of claim 9, wherein the processing circuit is further configured to:
determine, in response to collecting the first activity data and the second activity data, additional data is required to generate the MDP score;
request, via the GUI, the additional data corresponding to performance parameters of the identified performance model, wherein the modeling further comprises modeling the additional data to generate the MDP score.

11. The system of claim 1, wherein the activity is an economic activity corresponding to a product or service offered by the provider, and wherein the MDP score increases a likelihood of approval of the economic activity compared to the likelihood of approval of the economic activity using the at least one performance indicator associated with the first exchanger or the second exchanger.

12. A method, comprising:
authenticating, by one or more processing circuits, a first exchanger and a second exchanger, wherein at least one of the first exchanger or the second exchanger is associated with a provider;
receiving, by the one or more processing circuits, a selection of at least one actionable element corresponding to an activity of the first exchanger and the second exchanger;
identifying, by the one or more processing circuits, a performance model based on the selection of the activity;
collecting, by the one or more processing circuits, at least one performance indicator associated with the first exchanger or the second exchanger;
collecting, by the one or more processing circuits, first activity data of the first exchanger and second activity data of the second exchanger;
modeling, by the one or more processing circuits using the performance model, the at least one performance indicator, the first activity data, and the second activity data to generate a multi-dimensional performance (MDP) score; and
providing, by the one or more processing circuits, the MDP score.

13. The method of claim 12, wherein modeling the at least one performance indicator, the first activity data, and the second activity data comprises:
analyzing the collected performance indicator, the first activity data, and the second activity data to identify one or more patterns or correlations associated with at least one of the first exchanger or the second exchanger; and
generating the MDP score utilizing the performance model to forecast future performance of both the first exchanger and the second exchanger based at least on one of (1) identified one or more patterns or correlations with one or more activity parameters, or (2) a weighted contribution of the performance indicator, the first activity data, and the second activity data.

14. The method of claim 12, wherein the first exchanger is a visible exchanger to the one or more processing circuits and the second exchanger is an invisible exchanger to the one or more processing circuits, wherein the visible exchanger shares (1) the at least one performance indicator and (2) at least two protected data objects with the one or more processing circuits, and wherein the invisible exchanger shares at least one of (1) unprotected data or (2) at least one protected data object with the one or more processing circuits, wherein the unprotected data is accessible to an unauthorized user.

15. The method of claim 12, wherein the first exchanger is a visible exchanger to the one or more processing circuits and the second exchanger is a foreign exchanger to the one or more processing circuits, wherein the visible exchanger shares (1) the at least one performance indicator and (2) at least one protected data object with the one or more processing circuits, and wherein the invisible exchanger shares (1) at least one foreign performance indicator and (2) at least one foreign protected data object with the one or more processing circuits.

16. The method of claim 12, wherein the first exchanger is a first invisible exchanger to the one or more processing circuits and the second exchanger is a second invisible exchanger to the one or more processing circuits, wherein the first invisible exchanger shares at least one of (1) unprotected data or (2) at least one protected data object with the one or more processing circuits, wherein the unprotected data is accessible to an unauthorized user, and wherein the second invisible exchanger shares at least one of (1) additional unprotected data or (2) at least one additional protected data object with the one or more processing circuits.

17. The method of claim 12, wherein the one or more processing circuits are further configured to:
generate and provide a graphical user interface comprising a plurality of future action recommendations to increase the MDP score, wherein the plurality of future action recommendations comprises (1) a first recommendation to increase the MDP score associated with the first exchanger, (2) a second recommendation to increase the MDP score associated with the second exchanger, and (3) a combined recommendation to increase the MDP score associated with both the first exchanger and the second exchanger, and wherein the actionable element is provided on the GUI.

18. The method of claim 12, wherein the activity is an economic activity corresponding to a product or service offered by the provider, and wherein the MDP score increases a likelihood of approval of the economic activity compared to the likelihood of approval of the economic activity using the at least one performance indicator associated with the first exchanger or the second exchanger.

19. One or more non-transitory computer-readable storage media having instructions stored thereon that, when executed by at least one processing circuit, causes the at least one processing circuit to:
authenticate a first exchanger and a second exchanger, wherein at least one of the first exchanger or the second exchanger is associated with a provider;
receive a selection of at least one actionable element corresponding to an activity of the first exchanger and the second exchanger;
identify a performance model based on the selection of the activity;
collect at least one performance indicator associated with the first exchanger or the second exchanger;
collect first activity data of the first exchanger and second activity data of the second exchanger;
model, using the performance model, the at least one performance indicator, the first activity data, and the second activity data to generate a multi-dimensional performance (MDP) score; and
provide the MDP score.

20. The one or more non-transitory computer-readable medium of claim 19, wherein the modelling using the performance model comprises:
generating a MDP subscore for each of the at least one performance indicator, the first activity data, and the second activity data;
assigning a performance score weight (PSW) to each of the at least one performance indicator, the first activity data, and the second activity data, wherein the PSW is based on a plurality of risk assessment factors;
updating each MDP subscore of the at least one performance indicator, the first activity data, and the second activity data, wherein updating each MDP score includes scaling each MDP score by the corresponding PSW to generate a plurality of weighted MDP subscores; and
aggregating the plurality of weighted MDP subscores to generate the MDP score, wherein the MDP score increases a likelihood of approval of the activity compared to the likelihood of approval of the activity using the at least one performance indicator associated with the first exchanger or the second exchanger.
